(19) United States
(12) Patent Application Publication
(10) Pub. No.: US 2025/0081722 A1
(43) Pub. Date: Mar. 6, 2025

(54) LIGHT EMITTING DEVICE AND DISPLAY PANEL

(71) Applicant: BOE Technology Group Co., Ltd., Beijing (CN)

(72) Inventors: Xueqin CHEN, Beijing (CN); Lei CHEN, Beijing (CN); Dan WANG, Beijing (CN); Lixia QIU, Beijing (CN)

(21) Appl. No.: 18/561,324

(22) PCT Filed: Feb. 28, 2023
(86) PCT No.: PCT/CN2023/078593

§ 371 Date: Nov. 16, 2023

(51) Int. Cl. H10K 50/19; H10K 50/16; H10K 50/18; H10K 85/60; H10K 101/40; H10K 102/00

(52) U.S. Cl. CPC H10K 50/19; H10K 50/16; H10K 50/18; H10K 85/622; H10K 85/631; H10K 85/654; H10K 85/6572; H10K 85/6574; H10K 85/6576; H10K 2101/40; H10K 2102/351

(57) ABSTRACT

The present disclosure provides a light emitting device and a display panel, and belongs to the field of display technology. The light emitting device includes an anode, a cathode, a plurality of light emitting units between the anode and the cathode, and a charge separation generation unit between every two adjacent light emitting units; the plurality of light emitting units include a first light emitting unit and a second light emitting unit, and the first light emitting unit is closer to the anode than the second light emitting unit; and the first light emitting unit at least includes a first electron transport sub-unit, the second light emitting unit at least includes a second electron transport sub-unit, and a thickness of the first electron transport sub-unit is less than that of the second electron transport sub-unit.

### TECHNICAL FIELD

The present disclosure relates to the field of display technology, in particular to a light emitting device and display panel.

### BACKGROUND

With the development of the display technology, people have higher and higher requirements on a display device, and an organic electroluminescent display (OLED) device has the advantages of high color saturation, low driving voltage, wide viewing angle display, flexibility, fast response speed, simple manufacturing process and the like with respect to a liquid crystal display (LCD) with a mature technology, so that an OLED display panel gradually becomes the development trend of the display device.

In a vehicle-mounted display screen scene requiring a long service life of the OLED device, the existing OLED device cannot meet the requirement for service life. Therefore, it is necessary to develop a tandem device to improve the service life of the light emitting device, and to improve the luminance of the entire light emitting device by means of a plurality of light emitting layers, thereby improving the service life of the light emitting device. However, since a charge separation generation layer CGL is disposed in the middle of the tandem device, electron generation and injection capabilities of the charge separation generation layer are weak as compared to the cathode, which causes an imbalance between electrons and holes transmitted to the light emitting layers to be recombined with each other.

### SUMMARY

The present disclosure is directed to solving at least one of the technical problems in the related art, and provides a light emitting device and a display panel.

In a first aspect, the technical solution adopted for solving the technical problems in the related art is a light emitting device, including an anode, a cathode, a plurality of light emitting units between the anode and the cathode, and a charge separation generation unit between every two adjacent light emitting units; the plurality of light emitting units include a first light emitting unit and a second light emitting unit, and the first light emitting unit is closer to the anode than the second light emitting unit; and the first light emitting unit at least includes a first electron transport sub-unit, the second light emitting unit at least includes a second electron transport sub-unit, and a thickness of the first electron transport sub-unit is less than that of the second electron transport sub-unit.

In some implementations, the first electron transport sub-unit includes a first hole blocking layer and a first electron transport layer, which are sequentially provided in a direction from the anode to the cathode; the second electron transport sub-unit includes a second hole blocking layer and a second electron transport layer, which are sequentially provided in the direction from the anode to the cathode; the charge separation generation unit includes an N-type doped charge generation layer and a P-type doped charge generation layer, which are sequentially provided in the direction from the anode to the cathode.

In some implementations, a sum of thicknesses of the first electron transport layer and the first hole blocking layer is a first thickness; a sum of thicknesses of the second electron transport layer and the second hole blocking layer is a second thickness; a difference between the second thickness and the first thickness is between 50 Å and 350 Å.

In some implementations, the difference between the thicknesses of the second electron transport layer and the first electron transport layer is between 50 Å and 300 Å.

In some implementations, the thickness of the first electron transport layer is less than that of the second electron transport layer.

In some implementations, the first electron transport sub-unit includes a first electron transport layer; the second electron transport sub-unit includes a second electron transport layer; and a difference between thicknesses of the second electron transport layer and the first electron transport layer is between 50 Å and 300 Å.

In some implementations, an absolute value of a difference between a LUMO level of a lowest unoccupied molecular orbital of the N-type doped charge generation layer and a LUMO level of a lowest unoccupied molecular orbital of the first electron transport layer is between 0.1 eV and 0.6 eV.

In some implementations, a material of the N-type doped charge generation layer is doped with ytterbium Yb or lithium Li; and a doping concentration of the ytterbium Yb or the lithium Li is greater than or equal to 1%.

In some implementations, the N-type doped charge generation layer has a thickness between 100 Å and 250 Å.

In some implementations, an absolute value of a difference between a LUMO level of the first electron transport layer and a LUMO level of the first hole blocking layer is between 0.1 eV and 0.8 eV.

In some implementations, an electron mobility of the first electron transport layer is greater than that of the first hole blocking layer.

In some implementations, a material of the first electron transport layer and a material of the second electron transport layer are the same.

In some implementations, a material of the first electron transport layer and a material of the second electron transport layer are different from each other; and an absolute value of a difference between an LUMO level of the first electron transport layer and an LUMO level of the second electron transport layer is between 0 eV and 0.4 eV.

In some implementations, a material of the first electron transport layer and a material of the second electron transport layer have the following general structural formula:

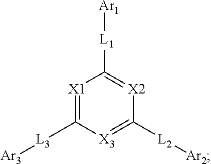

where, X₁, X₂ and X₃ each independently represent carbon C or nitrogen N, and at least one of X₁, X₂ and X₃ is N; L₁, L₂ and L₃ each independently represent a connecting group and any one selected from a single bond, a substituted or unsubstituted C6 to C20 aryl group and a substituted or unsubstituted C5 to C20 heteroaryl group; Ar₁, Ar₂ and Ar₃ each independently represent any one selected from a substituted or unsubstituted C6 to C20 aryl group and a substituted or unsubstituted C5 to C20 heteroaryl group.

In some implementations, the structure of each of the material of the first electron transport layer and the material of the second electron transport layer includes any one of:

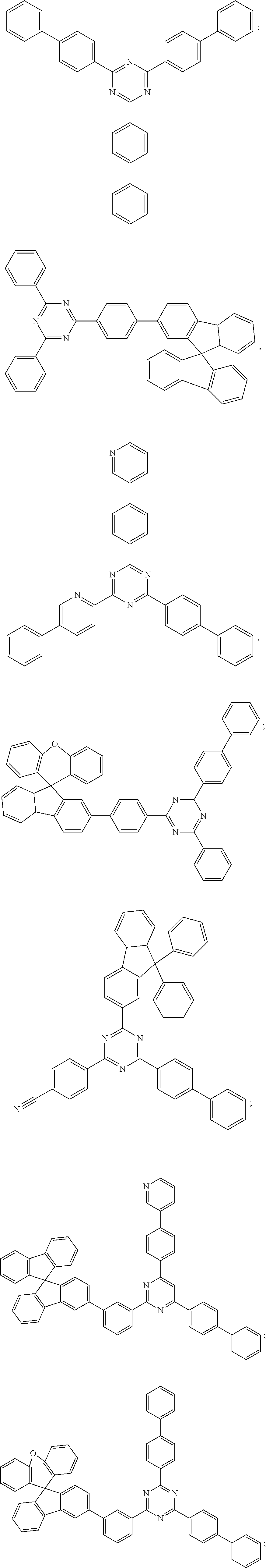

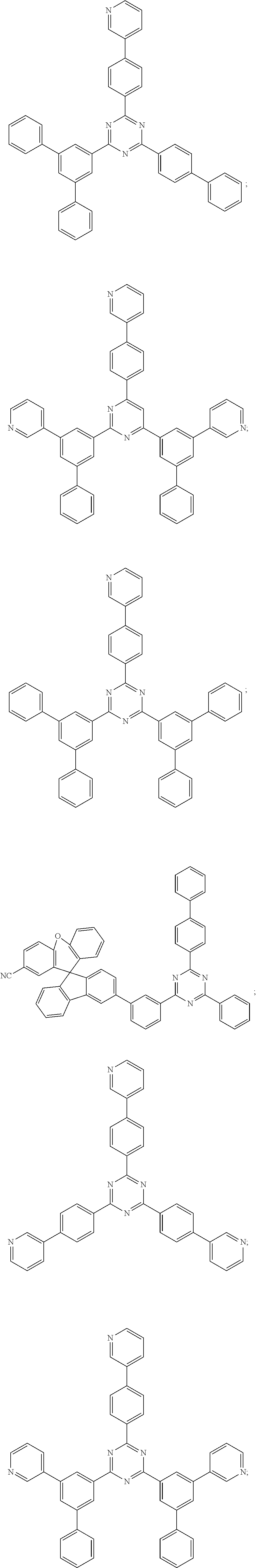

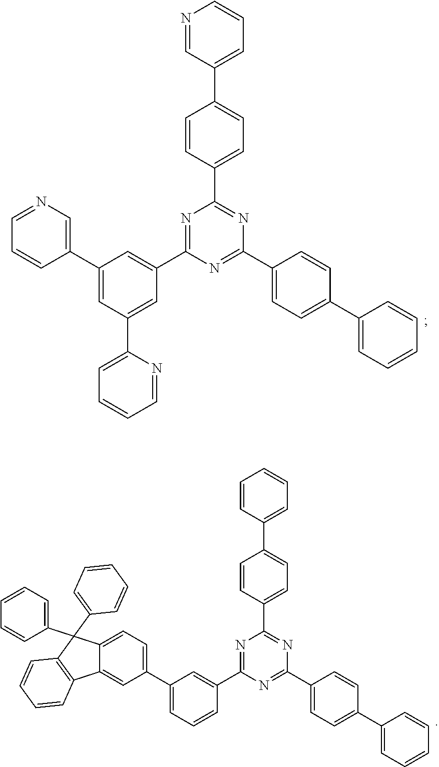 [SMILES: c1ccc(-c2ccc(-c3nc(-c4ccc(-c5cccnc5)cc4)nc(-c4cc(-c5cccnc5)cc(-c5ccccn5)c4)n3)cc2)cc1 ; c1ccc(-c2ccc(-c3nc(-c4ccc(-c5ccccc5)cc4)nc(-c4cccc(-c5ccc6c(c5)-c5ccccc5C6(c5ccccc5)c5ccccc5)c4)n3)cc2)cc1]

In some implementations, the first light emitting unit further includes a first hole transport sub-unit including a first hole transport layer and a first hole auxiliary layer, which are sequentially provided in a direction from the anode to the cathode; and the second light emitting unit further includes a second hole transport sub-unit including a second hole transport layer and a second hole auxiliary layer, which are sequentially provided in the direction from the anode to the cathode.

In some implementations, materials of the first hole auxiliary layer and the second hole auxiliary layer have the following general structural formula:

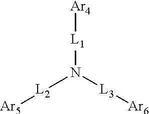

where L₁, L₂ and L₃ each independently represent a connecting group and any one selected from a single bond, a substituted or unsubstituted C6 to C20 aryl group and a substituted or unsubstituted C5 to C20 heteroaryl group; Ar₄, Ar₅ and Ar₆ all independently represent any one selected from a C6 to C50 aryl group and a substituted or unsubstituted C5 to C50 heteroaryl group, a fluorene-based material, a dibenzo five-membered ring structure and adamantane.

In some implementations, a structure of the fluorene-based material includes at least one of:

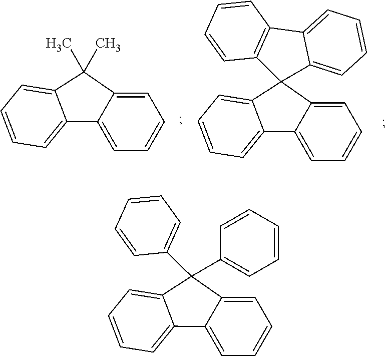

In some implementations, a structure of each of the material of the first hole auxiliary layer including the fluorene-based material and the material of the second hole auxiliary layer including the fluorene-based material includes any one of:

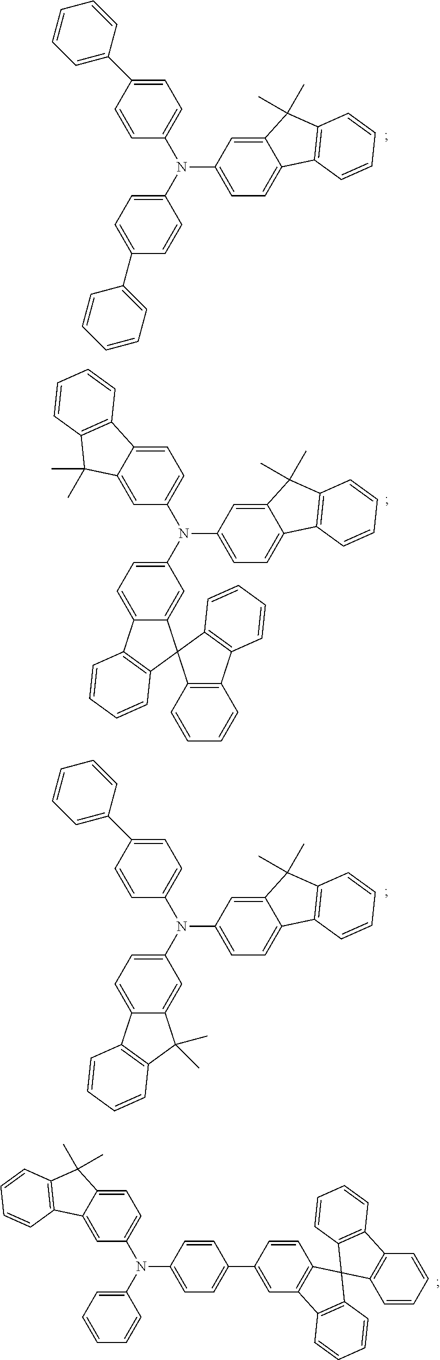

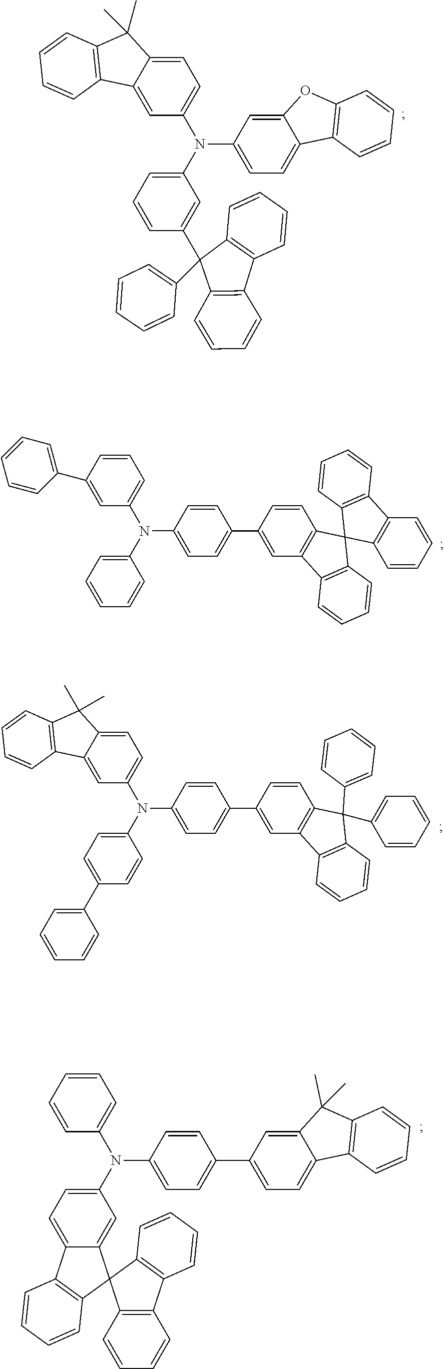 [SMILES: CC1(C)c2ccccc2-c2cc(N(c3cccc(C4(c5ccccc5)c5ccccc5-c5ccccc54)c3)c3ccc4c(c3)oc3ccccc34)ccc21 ; c1ccc(-c2cccc(N(c3ccccc3)c3ccc(-c4ccc5c(c4)-c4ccccc4C54c5ccccc5-c5ccccc54)cc3)c2)cc1 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; CC1(C)c2ccccc2-c2ccc(-c3ccc(N(c4ccccc4)c4ccc5c(c4)C4(c6ccccc6-c6ccccc64)c4ccccc4-5)cc3)cc21]

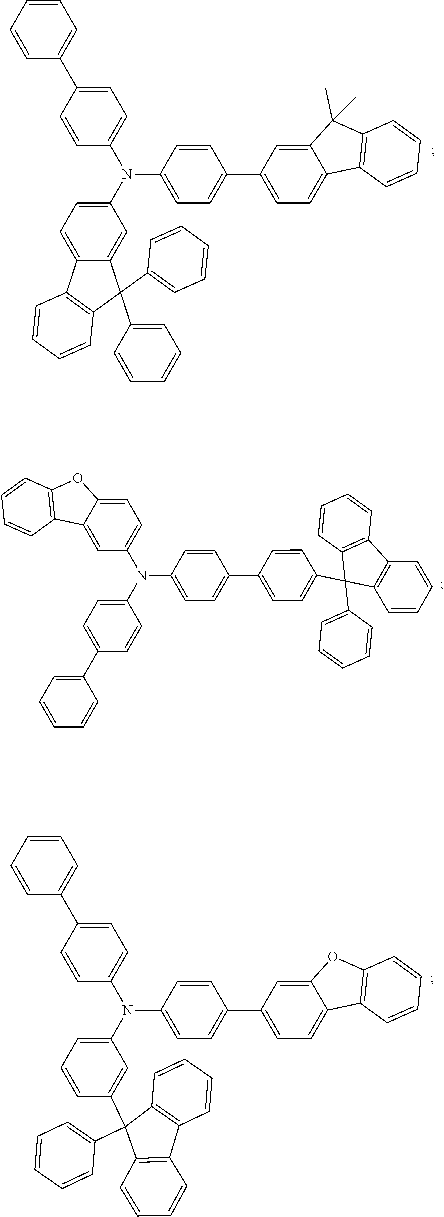 [SMILES: CC1(C)c2ccccc2-c2ccc(-c3ccc(N(c4ccc(-c5ccccc5)cc4)c4ccc5c(c4)C(c4ccccc4)(c4ccccc4)c4ccccc4-5)cc3)cc21 ; c1ccc(-c2ccc(N(c3ccc(-c4ccc(C5(c6ccccc6)c6ccccc6-c6ccccc65)cc4)cc3)c3ccc4oc5ccccc5c4c3)cc2)cc1 ; c1ccc(-c2ccc(N(c3ccc(-c4ccc5c(c4)oc4ccccc45)cc3)c3cccc(C4(c5ccccc5)c5ccccc5-c5ccccc54)c3)cc2)cc1]

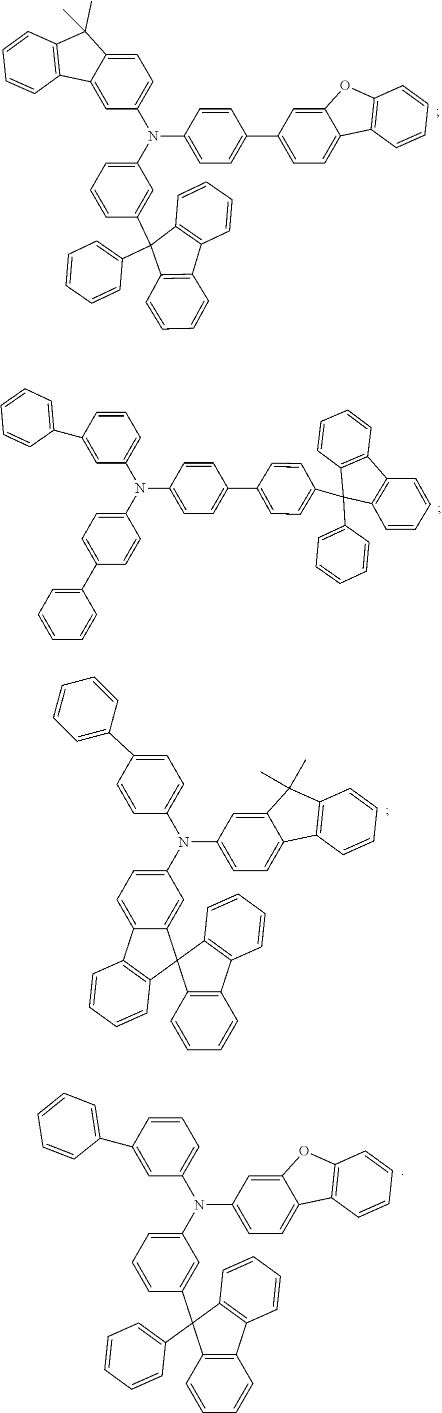

In some implementations, the dibenzo five-membered ring structure includes a structure of:

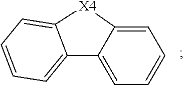

where, X4 is nitrogen N, oxygen O or sulfur S.

In some implementations, a structure of each of a material of the first hole auxiliary layer containing the dibenzo five-membered ring structure and a material of the second hole auxiliary layer containing the dibenzo five-membered ring structure includes any one of:

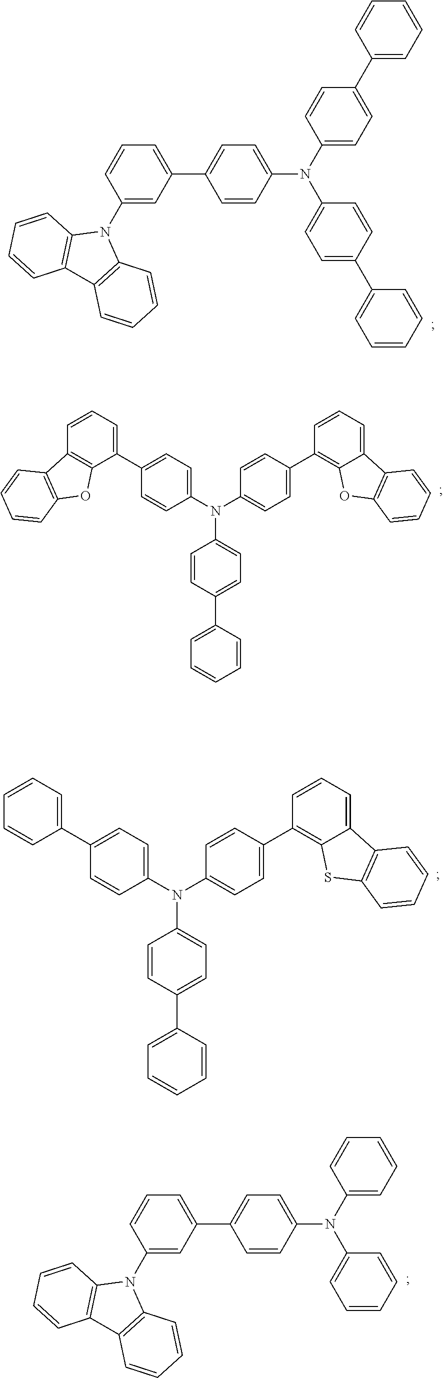 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccccc4)cc3)c3ccc(-c4cccc5c4sc4ccccc45)cc3)cc2)cc1 ; c1ccc(N(c2ccccc2)c2ccc(-c3cccc(-n4c5ccccc5c5ccccc54)c3)cc2)cc1]

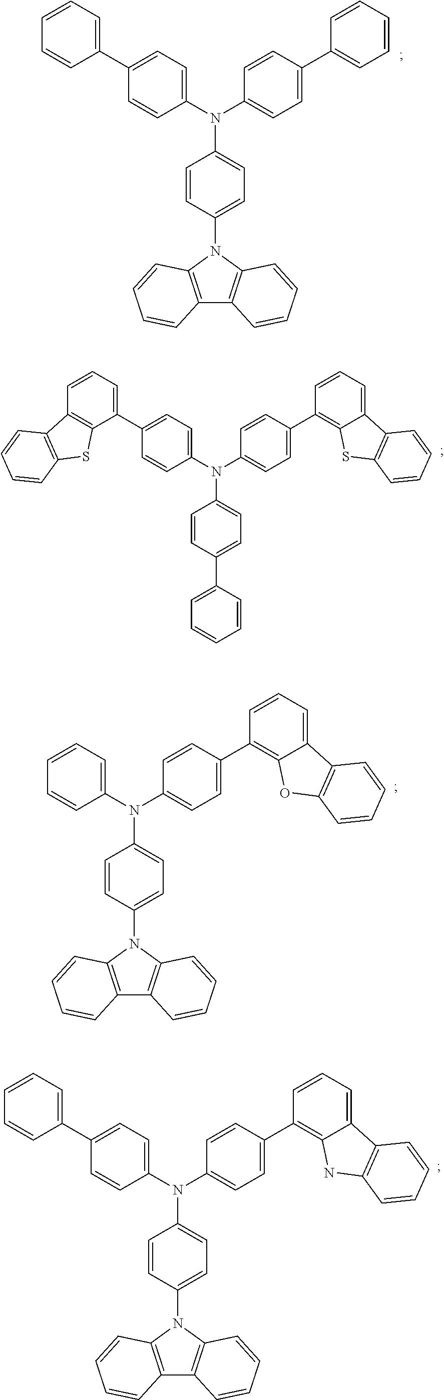 [SMILES: c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4cccc5c4sc4ccccc45)cc3)c3ccc(-c4cccc5c4sc4ccccc45)cc3)cc2)cc1 ; c1ccc(N(c2ccc(-c3cccc4c3oc3ccccc34)cc2)c2ccc(-n3c4ccccc4c4ccccc43)cc2)cc1 ; c1ccc(-c2ccc(N(c3ccc(-c4cccc5c4[nH]c4ccccc45)cc3)c3ccc(-n4c5ccccc5c5ccccc54)cc3)cc2)cc1]

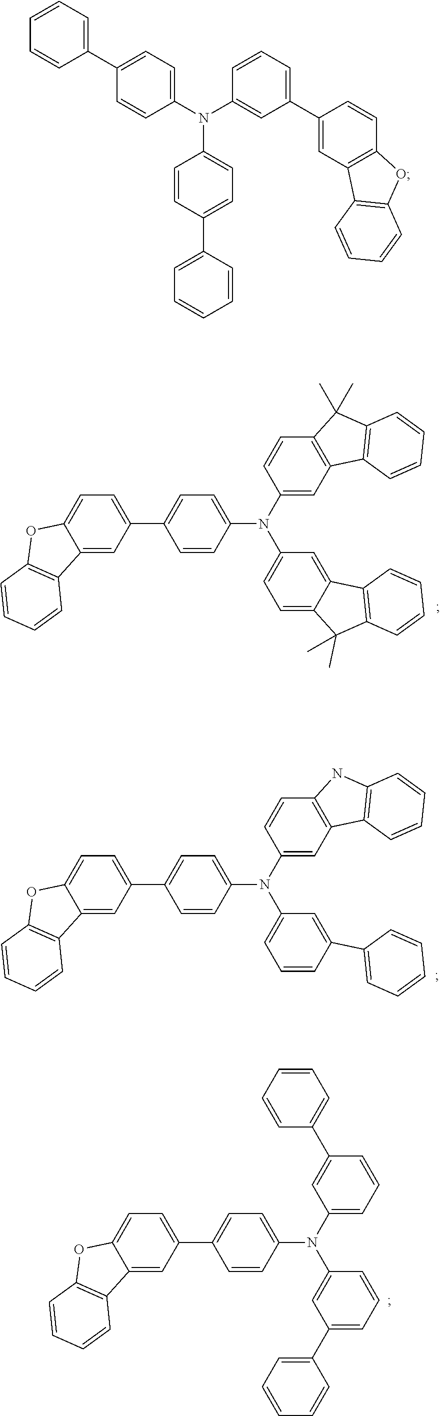 [SMILES: c1ccc(-c2ccc(N(c3ccc(-c4ccccc4)cc3)c3cccc(-c4ccc5oc6ccccc6c5c4)c3)cc2)cc1 ; CC1(C)c2ccccc2-c2cc(N(c3ccc(-c4ccc5oc6ccccc6c5c4)cc3)c3ccc4c(c3)-c3ccccc3C4(C)C)ccc21 ; c1ccc(-c2cccc(N(c3ccc(-c4ccc5oc6ccccc6c5c4)cc3)c3ccc4[nH]c5ccccc5c4c3)c2)cc1 ; c1ccc(-c2cccc(N(c3ccc(-c4ccc5oc6ccccc6c5c4)cc3)c3cccc(-c4ccccc4)c3)c2)cc1]

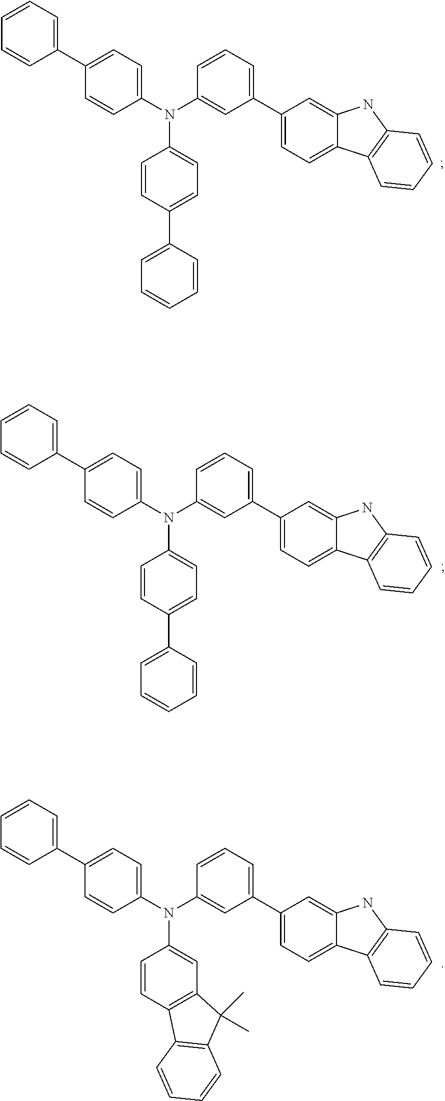 [SMILES: c1ccc(-c2ccc(N(c3ccc(-c4ccccc4)cc3)c3cccc(-c4ccc5c(c4)[nH]c4ccccc45)c3)cc2)cc1 ; c1ccc(-c2ccc(N(c3ccc(-c4ccccc4)cc3)c3cccc(-c4ccc5c(c4)[nH]c4ccccc45)c3)cc2)cc1 ; CC1(C)c2ccccc2-c2ccc(N(c3ccc(-c4ccccc4)cc3)c3cccc(-c4ccc5c(c4)[nH]c4ccccc45)c3)cc21]

In some implementations, a structure of the material of adamantane includes:

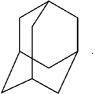

In some implementations, a structure of each of the material of the first hole auxiliary layer containing the adamantane and the material of the second hole auxiliary layer containing the adamantane includes any one of:

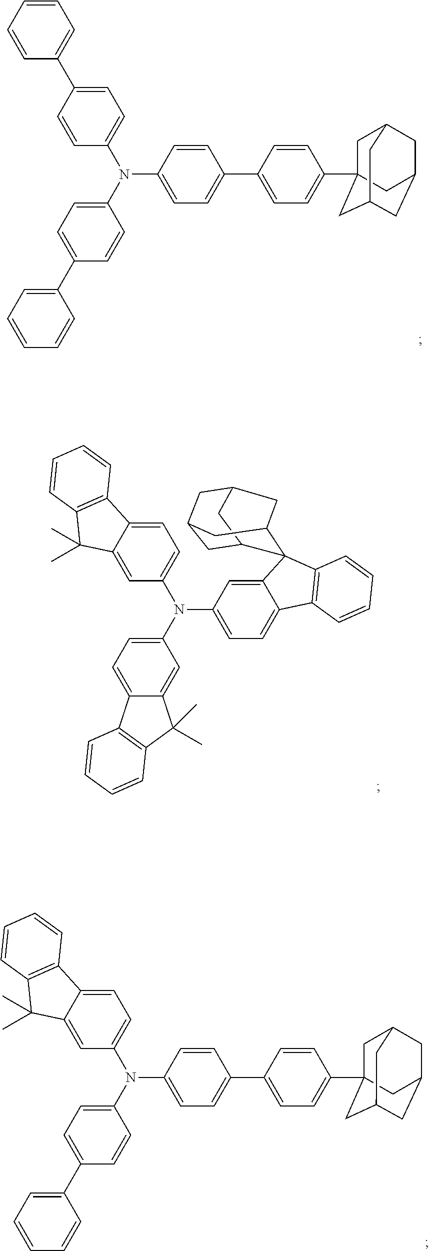 [SMILES: c1ccc(-c2ccc(N(c3ccc(-c4ccccc4)cc3)c3ccc(-c4ccc(C56CC7CC(CC(C7)C5)C6)cc4)cc3)cc2)cc1 ; CC1(C)c2ccccc2-c2ccc(N(c3ccc4c(c3)C(C)(C)c3ccccc3-4)c3ccc4c(c3)C3(c5ccccc5-4)C4CC5CC(C4)CC3C5)cc21 ; CC1(C)c2ccccc2-c2ccc(N(c3ccc(-c4ccccc4)cc3)c3ccc(-c4ccc(C56CC7CC(CC(C7)C5)C6)cc4)cc3)cc21]

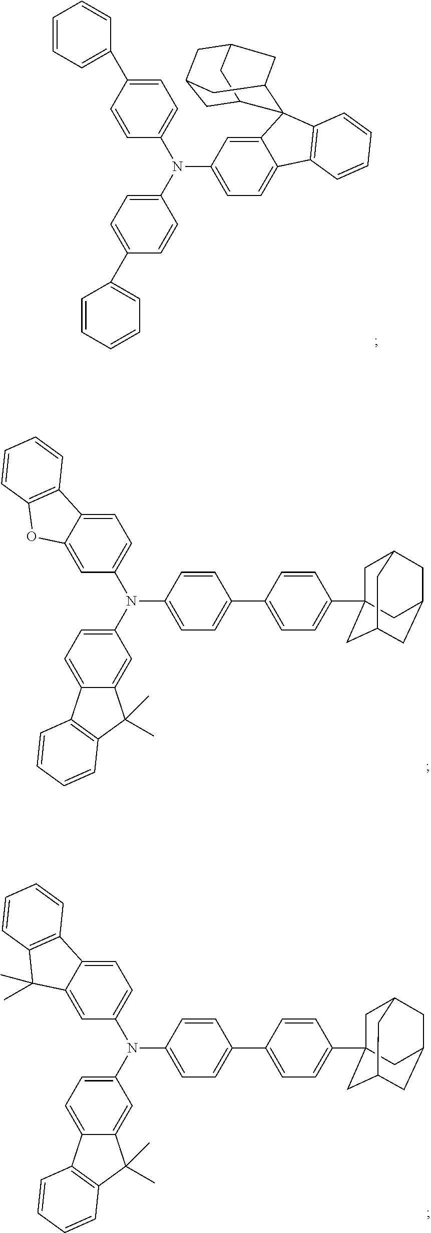 [SMILES: c1ccc(-c2ccc(N(c3ccc(-c4ccccc4)cc3)c3ccc4c(c3)C3(c5ccccc5-4)C4CC5CC(C4)CC3C5)cc2)cc1 ; CC1(C)c2ccccc2-c2ccc(N(c3ccc(-c4ccc(C56CC7CC(CC(C7)C5)C6)cc4)cc3)c3ccc4c(c3)oc3ccccc34)cc21 ; CC1(C)c2ccccc2-c2ccc(N(c3ccc(-c4ccc(C56CC7CC(CC(C7)C5)C6)cc4)cc3)c3ccc4c(c3)C(C)(C)c3ccccc3-4)cc21]

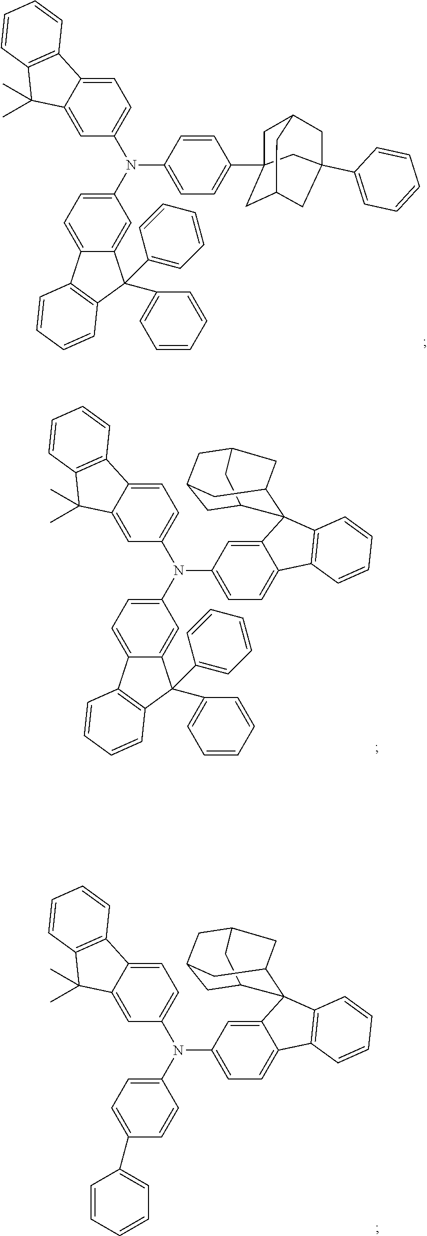 [SMILES: CC1(C)c2ccccc2-c2ccc(N(c3ccc(C45CC6CC(CC(c7ccccc7)(C6)C4)C5)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-4)C4CC5CC(C4)CC3C5)cc21 ; CC1(C)c2ccccc2-c2ccc(N(c3ccc(-c4ccccc4)cc3)c3ccc4c(c3)C3(c5ccccc5-4)C4CC5CC(C4)CC3C5)cc21]

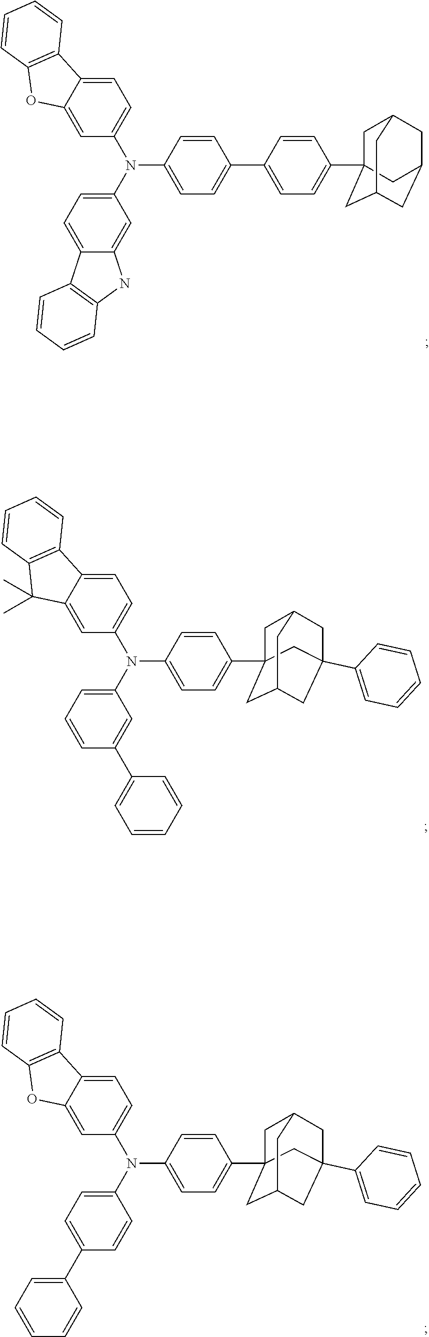 [SMILES: c1ccc2c(c1)[nH]c1cc(N(c3ccc(-c4ccc(C56CC7CC(CC(C7)C5)C6)cc4)cc3)c3ccc4c(c3)oc3ccccc34)ccc12 ; CC1(C)c2ccccc2-c2ccc(N(c3ccc(C45CC6CC(CC(c7ccccc7)(C6)C4)C5)cc3)c3cccc(-c4ccccc4)c3)cc21 ; c1ccc(-c2ccc(N(c3ccc(C45CC6CC(CC(c7ccccc7)(C6)C4)C5)cc3)c3ccc4c(c3)oc3ccccc34)cc2)cc1]

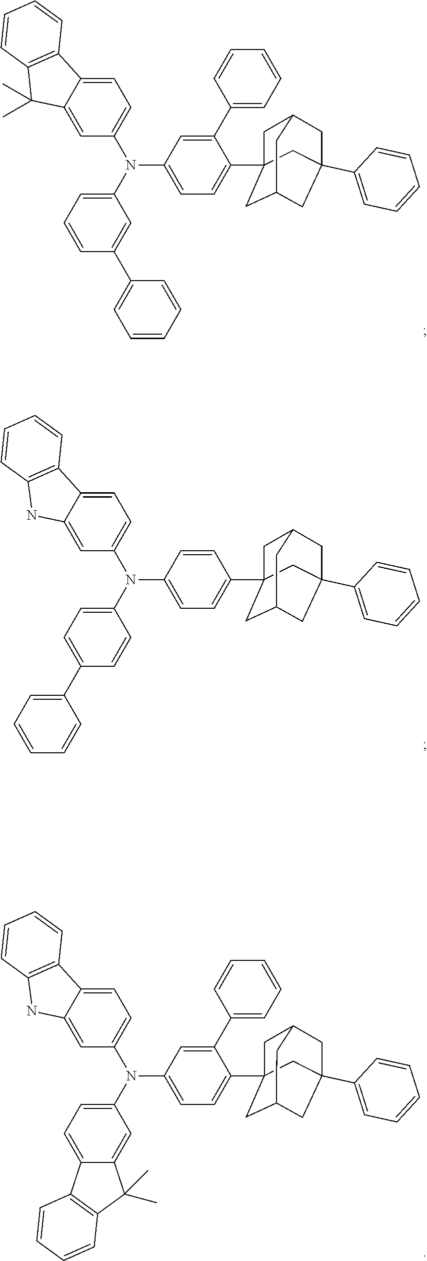 [SMILES: CC1(C)c2ccccc2-c2ccc(N(c3cccc(-c4ccccc4)c3)c3ccc(C45CC6CC(CC(c7ccccc7)(C6)C4)C5)c(-c4ccccc4)c3)cc21 ; c1ccc(-c2ccc(N(c3ccc(C45CC6CC(CC(c7ccccc7)(C6)C4)C5)cc3)c3ccc4c(c3)[nH]c3ccccc34)cc2)cc1 ; CC1(C)c2ccccc2-c2ccc(N(c3ccc(C45CC6CC(CC(c7ccccc7)(C6)C4)C5)c(-c4ccccc4)c3)c3ccc4c(c3)[nH]c3ccccc34)cc21]

In a second aspect, an embodiment of the present disclosure further provides a display panel, including the light emitting device according to any one of the above embodiments.

In some implementations, the first light emitting unit includes a first hole transport sub-unit at least including a first hole auxiliary layer; and the second light emitting unit includes a second hole transport sub-unit at least including a second hole auxiliary layer; the display panel includes a red light emitting device, a green light emitting device, and a blue light emitting device; where a thickness of the first hole auxiliary layer of the red light emitting device is greater than that of the first hole auxiliary layer of the green light emitting device, and the thickness of the first hole auxiliary layer of the green light emitting device is greater than that of the first hole auxiliary layer of the blue light emitting device; and a thickness of the second hole auxiliary layer of the red light emitting device is greater than that of the second hole auxiliary layer of the green light emitting device, and the thickness of the second hole auxiliary layer of the green light emitting device is greater than that of the second hole auxiliary layer of the blue light emitting device.

In some implementations, the first light emitting unit includes a first hole transport sub-unit at least including a first hole auxiliary layer; and the second light emitting unit includes a second hole transport sub-unit at least including a second hole auxiliary layer; the display panel includes a red light emitting device, a green light emitting device, and a blue light emitting device; wherein a hole mobility of the first hole auxiliary layer of the red light emitting device is greater than that of the first hole auxiliary layer of the green light emitting device, and the hole mobility of the first hole auxiliary layer of the green light emitting device is greater than that of the first hole auxiliary layer of the blue light emitting device; and a hole mobility of the second hole auxiliary layer of the red light emitting device is greater than that of the second hole auxiliary layer of the green light emitting device, and the hole mobility of the second hole auxiliary layer of the green light emitting device is greater than that of the second hole auxiliary layer of the blue light emitting device.

In some implementations, the first light emitting unit includes a first hole transport sub-unit at least including a first hole auxiliary layer; and the second light emitting unit includes a second hole transport sub-unit at least including a second hole auxiliary layer; and the display panel includes a red light emitting device, a green light emitting device, and a blue light emitting device; where a material of the first hole auxiliary layer and a material of the second hole auxiliary layer in the red light emitting device at least include adamantane; a material of the first hole auxiliary layer and a material of the second hole auxiliary layer in the green light emitting device at least include fluorene-based material; and a material of the first hole auxiliary layer and a material of the second hole auxiliary layer in the blue light emitting device at least include a dibenzo five-membered ring structure.

### BRIEF DESCRIPTION OF DRAWINGS

FIG. 1 is a schematic diagram of a light emitting device according to an embodiment of the present disclosure;

FIG. 2 is a schematic diagram of a specific structure of an exemplary light emitting device according to an embodiment of the present disclosure;

FIG. 3 is a schematic diagram of a display panel according to an embodiment of the present disclosure; and

FIG. 4 is a schematic diagram of some layers in a display panel according to an embodiment of the present disclosure.

Reference numbers are: 1. an anode; 2. a cathode; 31. a first light emitting unit; 32. a second light emitting unit; 4. a charge separation generation unit; 311. a first hole transport sub-unit; 312. a first electron transport sub-unit; EML1, a first light emitting layer; 321. a second hole transport sub-unit; 322. a second electron transport sub-unit; EML2, a second light emitting layer; HIL1, a first hole injection layer; HTL1, a first hole transport layer; prime1, a first hole auxiliary layer; HBL1, a first hole blocking layer; ETL1, a first electron transport layer; N-CGL, an N-type doped charge generation layer; P-CGL, a P-type doped charge generation layer; HTL2, a second hole transport layer; prime2, a second hole auxiliary layer; HBL2, a second hole blocking layer; ETL2, a second electron transport layer; EIL2, a second electron injection layer; 01. a red light emitting device; 02. a green light emitting device; 03. a blue light emitting device.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few, not all of, embodiments of the present disclosure. Components of the embodiments of the present disclosure, as generally described and illustrated in the drawings herein, could be arranged and designed in a wide variety of different configurations. Thus, the following detailed description of the embodiments of the present disclosure in the drawings is not intended to limit the protective scope of the present disclosure, but is merely representative of selected embodiments of the present disclosure. All other embodiments, which can be derived by a person skilled in the art from the embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising/comprise”, “including/includes”, or the like, means that the element or item preceding the term contains the element or item listed after the term and its equivalent, but does not exclude other elements or items. The term “connected/connecting”, “coupled/coupling”, or the like is not limited to physical or mechanical connections, but may include electrical connections, whether direct or indirect connections. The terms “upper/on”, “lower/under”, “left”, “right”, and the like are used only for indicating relative positional relationships, and when the absolute position of an object being described is changed, the relative positional relationships may also be changed accordingly.

Reference to “a plurality or a number of” in the present disclosure means two or more. Reference to “and/or” describes association relationships among associated objects, indicating that there may be three relationships. For example, A and/or B may indicate three cases, that is, A alone, A and B, or B alone. The character “/” generally indicates that the associated objects before and after the “/” are in an “or” relationship.

In the related art, a charge separation generation layer CGL is disposed in the middle of a tandem device, so that electron generation and injection capabilities of the charge separation generation layer are weak as compared to the cathode. Thus, a light emitting layer close to the cathode receives electrons more rapidly than a light emitting layer close to an anode, which results in an imbalance between electrons and holes received by the plurality of light emitting layers stacked in the light emitting device, thereby affecting the efficiency of the light emitting device.

In view of above, the present disclosure provides a light emitting device, and an electron transport capability of a first light emitting unit 31 of the light emitting device is improved, so that the electron transport is smoother, and the holes and electrons in the first light emitting unit 31 and a second light emitting unit 32 can be balanced, thereby improving the efficiency of the light emitting device.

Specifically, the light emitting device includes an anode 1, a cathode 2, a plurality of light emitting units disposed between the anode 1 and the cathode 2, and a charge separation generation unit 4 disposed between every two adjacent light emitting units; the plurality of light emitting units include a first light emitting unit 31 and a second light emitting unit 32, and the first light emitting unit 31 is closer to the anode 1 than the second light emitting unit 32; the first light emitting unit 31 at least includes a first electron transport sub-unit 312, the second light emitting unit 32 at least includes a second electron transport sub-unit 322, and a thickness of the first electron transport sub-unit 312 is less than that of the second electron transport sub-unit 322.

The thickness of the first electron transport sub-unit 312 is less than that of the second electron transport sub-unit 322 in the embodiment of the present disclosure, which improves the electron transport capability of the first light emitting unit 31, so that the electron transport is smoother, to balance the holes and electrons in the first light emitting unit 31 and the second light emitting unit 32, thereby improving the efficiency of the light emitting device.

It should be noted that the light emitting device in the present disclosure is not limited to include only one first light emitting unit and only one second light emitting unit, and may further include at least one third light emitting unit disposed between the first light emitting unit and the second light emitting unit, where parameters of layer structure in the at least one third light emitting unit may refer to parameters of layer structures of the first light emitting unit and the second light emitting unit, and specific values of the parameter are not limited in the embodiments of the present disclosure.

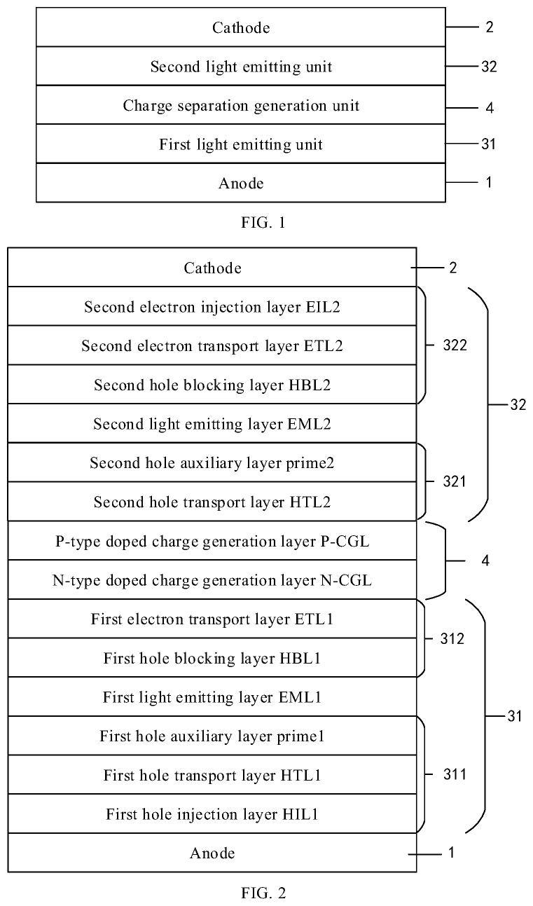

A specific structure of the light emitting device will be described in detail below by taking an example in which the light emitting device includes one first light emitting unit and one second light emitting unit. FIG. 1 is a schematic diagram of a light emitting device according to an embodiment of the present disclosure; as shown in FIG. 1, the light emitting device includes an anode 1, a cathode 2, a plurality of light emitting units disposed between the anode 1 and the cathode 2, and a charge separation generation unit 4 disposed between adjacent light emitting units. The plurality of light emitting units include a first light emitting unit 31 and a second light emitting unit 32, and the first light emitting unit 31 is closer to the anode 1 than the second light emitting unit 32.

The first light emitting unit 31 includes at least a first electron transport sub-unit 312. In some implementations, the first light emitting unit 31 includes a first light emitting layer EML1 and the first electron transport sub-unit 312 disposed on a side of the first light emitting layer EML1 away from the anode 1. Alternatively, the first light emitting unit 31 includes a first hole transport sub-unit 311, the first light emitting layer EML1, and the first electron transport sub-unit 312, which are sequentially disposed in a direction from the anode 1 to the cathode 2. Here, the first electron transport sub-unit 312 is configured to transport electrons generated by the charge separation generation unit 4 to the first light emitting layer EML1. The first hole transport sub-unit 311 is configured to transport holes generated by the anode 1 or the charge separation generation unit 4 to the first light emitting layer EML1. The first light emitting layer EML1 is configured to recombine the holes and the electrons to form excitons to emit light.

The second light emitting unit 32 includes at least a second electron transport sub-unit 322. In some implementations, the second light emitting unit 32 includes a second light emitting layer EML2 and the second electron transport sub-unit 322 disposed on a side of the second light emitting layer EML2 away from the anode 1. Alternatively, the second light emitting unit 32 includes a second hole transport sub-unit 321, the second light emitting layer EML2, and the second electron transport sub-unit 322, which are sequentially disposed in the direction from the anode 1 to the cathode 2. Here, the second electron transport sub-unit 322 is configured to transport electrons generated by the cathode 2 to the second light emitting layer EML2. The second hole transport sub-unit 321 is configured to transport holes generated by the charge separation generation unit 4 to the second light emitting layer EML2. The second light emitting layer EML2 is configured to recombine the holes and the electrons to form excitons to emit light.

A thickness of the first electron transport sub-unit 312 is less than that of the second electron transport sub-unit 322. The light emitting device in this embodiment includes at least one first light emitting unit 31, the thickness of the first electron transport sub-unit 312 in each first light emitting unit 31 is less than the thickness of the second electron transport sub-unit 322. By improving the electron transport capability of each first light emitting unit 31 to balance holes and electrons in the first light emitting layer EML1 and the second light emitting layer EML2, the efficiency of the entire light emitting device is improved.

It should be noted that the light emitting device in the embodiment of the present disclosure includes at least one first light emitting unit 31. For facilitating understanding of the embodiment of the present disclosure, the light emitting device provided in the present disclosure is described below by taking an example in which the light emitting device includes only one first light emitting unit 31 and only one second light emitting unit 32.

FIG. 2 is a schematic diagram of a specific structure of an exemplary light emitting device according to an embodiment of the present disclosure; as shown in FIG. 2, the light emitting device includes one first light emitting unit 31 and one second light emitting unit 32, and the first light emitting unit 31 is closer to the anode 1 than the second light emitting unit 32. The first light emitting unit 31 includes a first hole transport sub-unit 311, a first light emitting layer EML1, and a first electron transport sub-unit 312, which are sequentially disposed in the direction from the anode 1 to the cathode 2. The first hole transport sub-unit 311 includes a first hole transport layer HTL1 and a first hole auxiliary layer prime1, which are sequentially disposed in the direction from the anode 1 to the cathode 2. Alternatively, the first hole transport sub-unit 311 includes a first hole injection layer HIL1, the first hole transport layer HTL1, and the first hole auxiliary layer prime1, which are sequentially disposed in the direction from the anode 1 to the cathode 2. The first electron transport sub-unit 312 includes a first hole blocking layer HBL1 and a first electron transport layer ETL1, which are sequentially disposed in the direction from the anode 1 to the cathode 2. Alternatively, the first electron transport sub-unit 312 includes the first hole blocking layer HBL1, the first electron transport layer ETL1, and a first electron injection layer, which are sequentially disposed in the direction from the anode 1 to the cathode 2. The second hole transport sub-unit 321 includes a second hole transport layer HTL2 and a second hole auxiliary layer prime2, which are sequentially disposed in the direction from the anode 1 to the cathode 2. Alternatively, the second hole transport sub-unit 321 includes a second hole injection layer, the first hole transport layer HTL1, and the second hole auxiliary layer prime2, which are sequentially disposed in the direction from the anode 1 to the cathode 2. The second electron transport sub-unit 322 includes a second hole blocking layer HBL2 and a second electron transport layer ETL2, which are sequentially disposed in the direction from the anode 1 to the cathode 2. Alternatively, the second electron transport sub-unit 322 includes the second hole blocking layer HBL2, the second electron transport layer ETL2, and a second electron injection layer EIL2, which are sequentially disposed in the direction from the anode 1 to the cathode 2. The charge separation generation unit 4 includes an N-type doped charge generation layer N-CGL and a P-type doped charge generation layer P-CGL, which are sequentially disposed in the direction from the anode 1 to the cathode 2.

For example, the N-type doped charge generation layer N-CGL is an N-type organic semiconductor. The P-type doped charge generation layer P-CGL is a P-type organic semiconductor. The N-type doped charge generation layer N-CGL and the P-type doped charge generation layer P-CGL may form a P/N junction structure, thereby forming electrons and holes. The N-type doped charge generation layer N-CGL injects the electrons into the electron transport sub-unit, and the P-type doped charge generation layer P-CGL injects the holes into the hole transport sub-unit.

In some implementations, as shown in FIG. 2, the first electron transport sub-unit 312 includes the first electron transport layer ETL1 and the first hole blocking layer HBL1, and the second electron transport sub-unit 322 includes the second electron transport layer ETL2 and the second hole blocking layer HBL2. A sum of thicknesses of the first electron transport layer ETL1 and the first hole blocking layer HBL1 is a first thickness H1; a sum of thicknesses of the second electron transport layer ETL2 and the second hole blocking layer HBL2 is a second thickness H2; a difference between the second thickness H2 and the first thickness H1 is between 50 Å and 350 Å.

A thickness of the first electron transport layer ETL1 is h(ETL1), a thickness of the first hole blocking layer HBL1 is h(HBL1), a thickness of the second electron transport layer ETL2 is h(ETL2), a thickness of the second hole blocking layer HBL2 is h(HBL2), where H1=h(ETL1)+h(HBL1), H2=h(ETL2)+h(HBL2), 50 Å≤(H2−H1)≤350 Å.

In some implementations, the thickness h(ETL1) of the first electron transport layer ETL1 is less than the thickness h(ETL2) of the second electron transport layer ETL2.

In some implementations, the thickness h(ETL1) of the first electron transport layer ETL1 is less than the thickness h(ETL2) of the second electron transport layer ETL2, and a difference between the thicknesses of the second electron transport layer ETL2 and the first electron transport layer ETL1 is between 50 Å and 300 Å, i.e., 50 Å≤h(ETL2)−h(ETL1)≤300 Å.

For example, the thickness of the first electron transport layer ETL1 is between 50 Å and 250 Å, for example, the thickness of the first electron transport layer ETL1 is 50 Å; the thickness of the second electron transport layer ETL2 is between 300 Å and 400 Å, for example, the thickness of the second electron transport layer ETL2 is 300 Å.

In the above embodiment, in the light emitting device, electrons in the first light emitting unit 31 are more smoothly transmitted than electrons in the second light emitting unit 32 in a case where the thickness of the first electron transport sub-unit 312 and the thickness of the second electron transport sub-unit 322 satisfy 50 Å≤(H2−H1)≤350 Å and 50 Å≤h(ETL2)−h(ETL1)≤300 Å.

In some implementations, the first electron transport sub-unit 312 includes only the first electron transport layer ETL1, and the second electron transport sub-unit 322 includes only the second electron transport layer ETL2. The thickness h(ETL1) of the first electron transport layer ETL1 is less than the thickness h(ETL2) of the second electron transport layer ETL2, and the difference between the thicknesses of the second electron transport layer ETL2 and the first electron transport layer ETL1 is between 50 Å and 300 Å, i.e., 50 Å≤h(ETL2)−h(ETL1)≤300 Å.

Here, in the light emitting device, electrons in the first light emitting unit 31 are more smoothly transmitted than electrons in the second light emitting unit 32 in a case where the thickness h(ETL1) of the first electron transport layer ETL1 and the thickness h(ETL2) of the second electron transport layer ETL2 satisfy 50 Å≤h(ETL2)−h(ETL1)≤300 Å.

In some implementations, an absolute value of a difference between an energy level of a lowest unoccupied molecular orbital (LUMO), i.e., LUMO level, of the N-type doped charge generation layer N-CGL and an LUMO level of the first electron transport layer ETL1 is between 0.1 eV and 0.6 eV.

For example, the LUMO level of the first electron transport layer ETL1 is between −3.25 eV and −2.95 eV, for example, the LUMO level of the first electron transport layer ETL1 is −3.15 eV. The LUMO level of the N-type doped charge generation layer N-CGL is between −3.05 eV and −2.90 eV, for example, the LUMO level of the N-type doped charge generation layer N-CGL is −2.97 eV.

In the present embodiment, the LUMO level of the N-type doped charge generation layer N-CGL, i.e., LUMO(N-CGL), and the LUMO level of the first electron transport layer ETL1, i.e., LUMO(ETL1) are adjusted and controlled, to satisfy 0.1 eV≤|LUMO(N-CGL)−LUMO(ETL1)|≤0.6 eV, so that the smoothness of injecting electrons from the N-type doped charge generation layer N-CGL to the first electron transport layer ETL1 is increased for the first light emitting unit 31 compared with the second light emitting unit 32, thereby improving the electron transport capability of the whole first light emitting unit 31, balancing the holes and electrons in the first light emitting layer EML1 and the second light emitting layer EML2, and improving the efficiency of the whole light emitting device.

In some implementations, a material of the N-type doped charge generation layer N-CGL is doped with ytterbium Yb or lithium Li; a doping concentration of ytterbium Yb or lithium Li is greater than or equal to 1%. Specifically, the ytterbium Yb or the lithium Li is doped in the organic semiconductor material at the doping concentration of 1%, which improves the electron generation capability of the N-type doped charge generation layer N-CGL.

It should be noted that the doping concentration herein may be understood as a molar mass ratio of the doping material (i.e., Yb or Li) to the material of the N-type doped charge generation layer N-CGL.

In some implementations, the N-type doped charge generation layer N-CGL has a thickness between 100 Å and 250 Å. For example, the thickness of the N-type doped charge generation layer N-CGL is between 175 Å and 185 Å, for example, the thickness of the N-type doped charge generation layer N-CGL is 180 Å.

In some implementations, an absolute value of a difference between the LUMO level of the first electron transport layer ETL1 and the LUMO level of the first hole blocking layer HBL1 is between 0.1 eV and 0.8 eV.

For example, the LUMO level of the first electron transport layer ETL1 is between −3.25 eV and −2.95 eV, for example, the LUMO level of the first electron transport layer ETL1 is −3.15 eV. The LUMO level of the first hole blocking layer HBL1 is between −2.85 eV and −2.55 eV, for example, the LUMO level of the first hole blocking layer HBL1 is −2.79 eV.

In the present embodiment, the LUMO level of the first electron transport layer ETL1, i.e., LUMO(ETL1), and the LUMO level of the first hole blocking layer HBL1, i.e., LUMO(HBL1), are adjusted and controlled, to satisfy 0.1 eV≤|LUMO(HBL1)−LUMO(ETL1)|≤0.8 eV, so that the smoothness of injecting electrons from the first electron transport layer ETL1 to the first hole transport layer HTL1 is increased for the first light emitting unit 31 compared with the second light emitting unit 32, thereby improving the electron transport capability of the whole first light emitting unit 31, balancing the holes and electrons in the first light emitting layer EML1 and the second light emitting layer EML2, and improving the efficiency of the whole light emitting device.

In some implementations, an electron mobility of the first electron transport layer ETL1 is greater than that of the first hole blocking layer HBL1, that is, μₑ(ETL1)>μₑ(HBL1), which can increase the smoothness of injecting electrons from the first electron transport layer ETL1 to the first hole transport layer HTL1, thereby improving the electron transport capability of the first light emitting unit 31 as a whole, to balance holes and electrons in the first light emitting layer EML1 and the second light emitting layer EML2, and improve the efficiency of the entire light emitting device.

For example, the electron mobility of the first electron transport layer ETL1 is between 3.6×10⁻⁶ cm²/(V·s) and 3.4×10⁻⁵ cm²/(V·s), the electron mobility of the first hole blocking layer HBL1 is between 8.1×10⁻⁷ cm²/(V·s) and 9.1×10⁻⁷ cm²/(V·s). For example, the electron mobility of the first hole blocking layer HBL1 is 8.6×10⁻⁷ cm²/(V·s).

In some implementations, the material of the first electron transport layer ETL1 and the material of the second electron transport layer ETL2 are the same, so that the process preparation cost can be saved.

In some implementations, the material of the first electron transport layer ETL1 and the material of the second electron transport layer ETL2 are different. In such case, an absolute value of a difference between the LUMO level of the first electron transport layer ETL1 and a LUMO level of the second electron transport layer ETL2, i.e., LUMO(ETL2), is between 0 eV and 0.4 eV, that is, 0≤|LUMO(ETL1)−LUMO(ETL2)|≤0.4 eV, thereby ensuring the smoothness of the electron injection of the first light emitting unit 31.

For example, the LUMO level of the first electron transport layer ETL1 is between −3.25 eV and −2.95 eV, and the LUMO level of the second electron transport layer ETL2 is between −3.25 eV and −2.95 eV.

In some implementations, the electron transport layer may be made of a material having an azine unit. In particular, the general structural formulas of the material of the first electron transport layer ETL1 and the material of the second electron transport layer ETL2 both have the following structure (I):

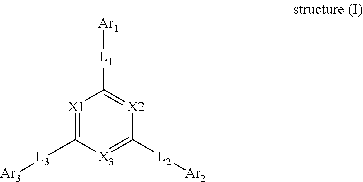

where, X₁, X₂ and X₃ each independently represent carbon C or nitrogen N, and at least one of X₁, X₂ or X₃ is N; L₁, L₂ and L₃ each independently represent a connecting group and any one selected from a single bond, a substituted or unsubstituted C6 to C20 aryl group and a substituted or unsubstituted C5 to C20 heteroaryl group; Ar₁, Ar₂ and Ar₃ each independently represent any one selected from a substituted or unsubstituted C6 to C20 aryl group and a substituted or unsubstituted C5 to C20 heteroaryl group.

Here, the azine has a strong electron transport capability, and the first electron transport layer ETL1 and the second electron transport layer ETL2 are made of the material having the azine unit, so that the electron transport capability of the first electron transport layer ETL1 can be improved, and the electron transport is smoother.

For example, the structures of the material of the first electron transport layer ETL1 and the material of the second electron transport layer ETL2 include any one of the following structures:

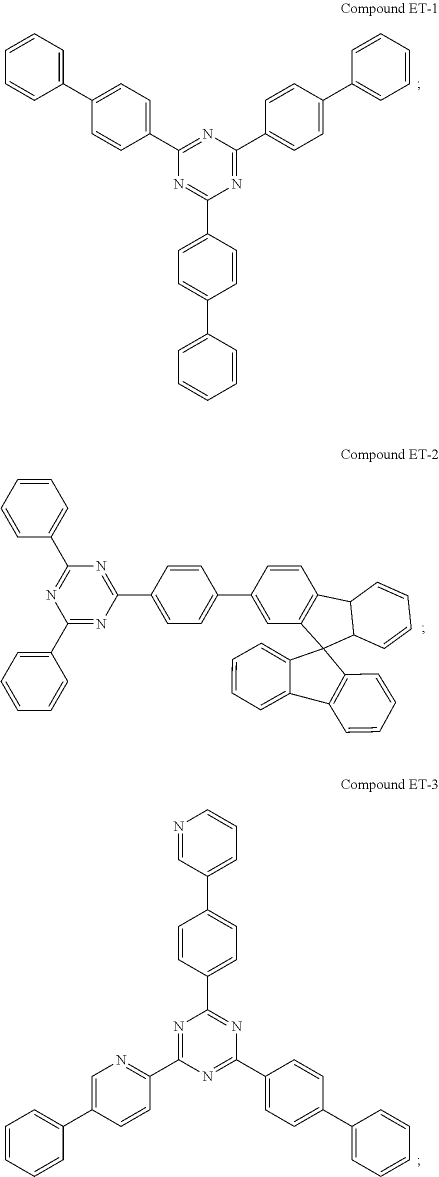 [SMILES: c1ccc(-c2ccc(-c3nc(-c4ccc(-c5ccccc5)cc4)nc(-c4ccc(-c5ccccc5)cc4)n3)cc2)cc1 ; C1=CC2c3ccc(-c4ccc(-c5nc(-c6ccccc6)nc(-c6ccccc6)n5)cc4)cc3C3(c4ccccc4-c4ccccc43)C2C=C1 ; c1ccc(-c2ccc(-c3nc(-c4ccc(-c5cccnc5)cc4)nc(-c4ccc(-c5ccccc5)cn4)n3)cc2)cc1]

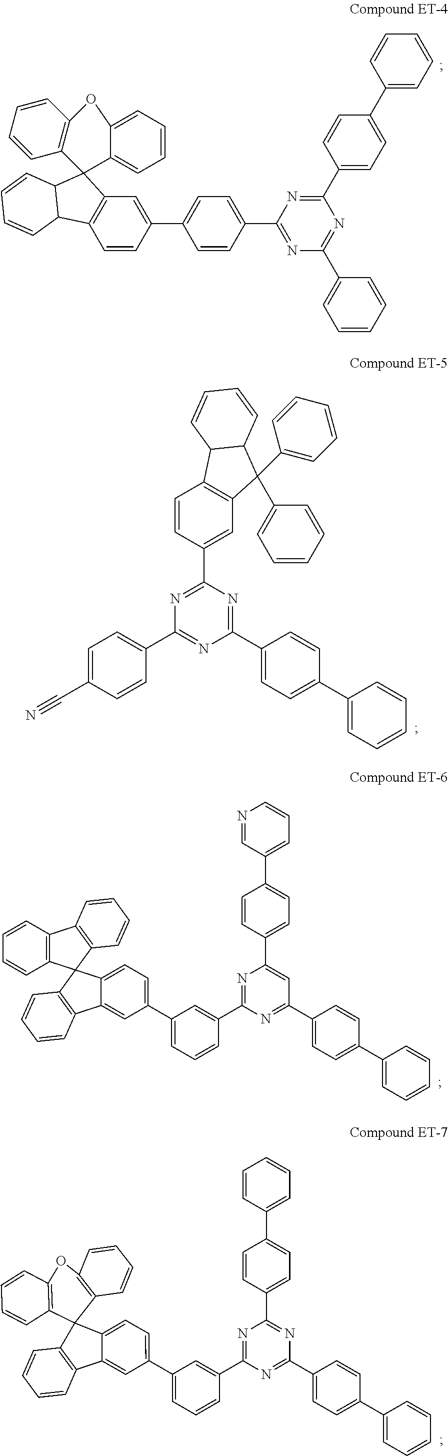 [SMILES: C1=CC2c3ccc(-c4ccc(-c5nc(-c6ccccc6)nc(-c6ccc(-c7ccccc7)cc6)n5)cc4)cc3C3(c4ccccc4Oc4ccccc43)C2C=C1 ; N#Cc1ccc(-c2nc(-c3ccc(-c4ccccc4)cc3)nc(-c3ccc4c(c3)C(c3ccccc3)(c3ccccc3)C3C=CC=CC43)n2)cc1 ; c1ccc(-c2ccc(-c3cc(-c4ccc(-c5cccnc5)cc4)nc(-c4cccc(-c5ccc6c(c5)-c5ccccc5C65c6ccccc6-c6ccccc65)c4)n3)cc2)cc1 ; c1ccc(-c2ccc(-c3nc(-c4ccc(-c5ccccc5)cc4)nc(-c4cccc(-c5ccc6c(c5)-c5ccccc5C65c6ccccc6Oc6ccccc65)c4)n3)cc2)cc1]

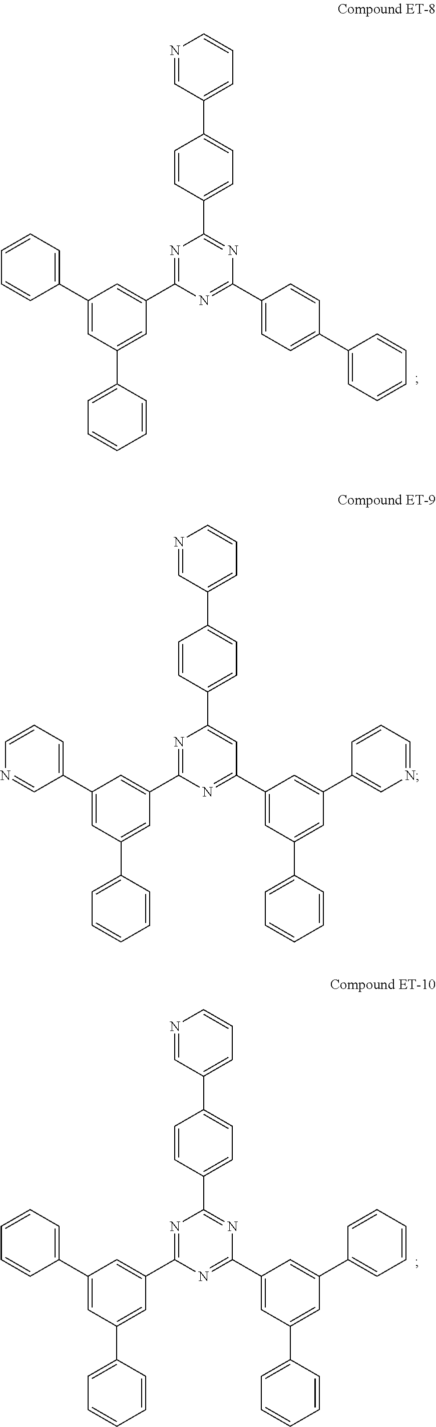 [SMILES: c1ccc(-c2ccc(-c3nc(-c4ccc(-c5cccnc5)cc4)nc(-c4cc(-c5ccccc5)cc(-c5ccccc5)c4)n3)cc2)cc1 ; c1ccc(-c2cc(-c3cccnc3)cc(-c3cc(-c4ccc(-c5cccnc5)cc4)nc(-c4cc(-c5ccccc5)cc(-c5cccnc5)c4)n3)c2)cc1 ; c1ccc(-c2cc(-c3ccccc3)cc(-c3nc(-c4ccc(-c5cccnc5)cc4)nc(-c4cc(-c5ccccc5)cc(-c5ccccc5)c4)n3)c2)cc1]

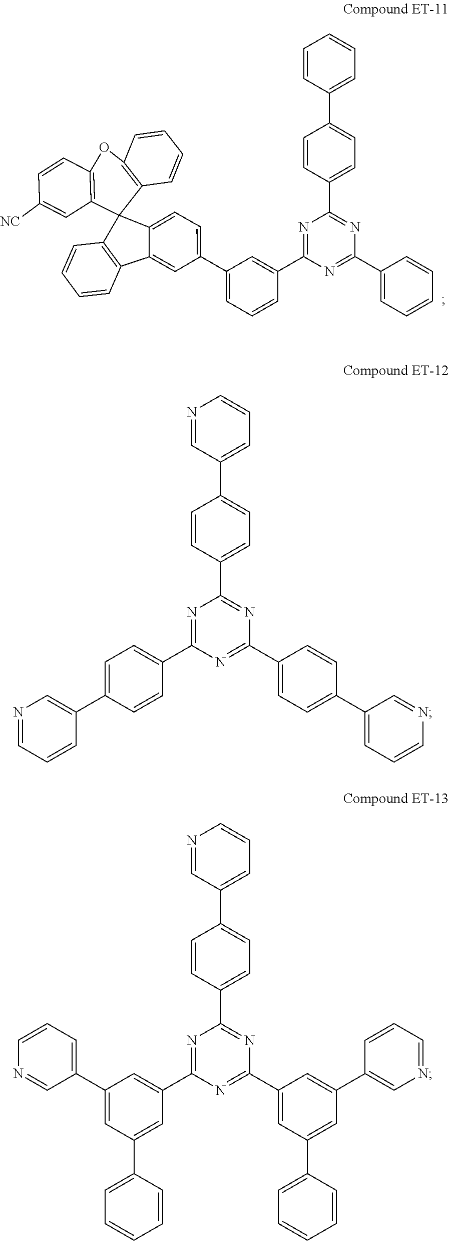 [SMILES: N#Cc1ccc2c(c1)C1(c3ccccc3O2)c2ccccc2-c2cc(-c3cccc(-c4nc(-c5ccccc5)nc(-c5ccc(-c6ccccc6)cc5)n4)c3)ccc21 ; c1cncc(-c2ccc(-c3nc(-c4ccc(-c5cccnc5)cc4)nc(-c4ccc(-c5cccnc5)cc4)n3)cc2)c1 ; c1ccc(-c2cc(-c3cccnc3)cc(-c3nc(-c4ccc(-c5cccnc5)cc4)nc(-c4cc(-c5ccccc5)cc(-c5cccnc5)c4)n3)c2)cc1]

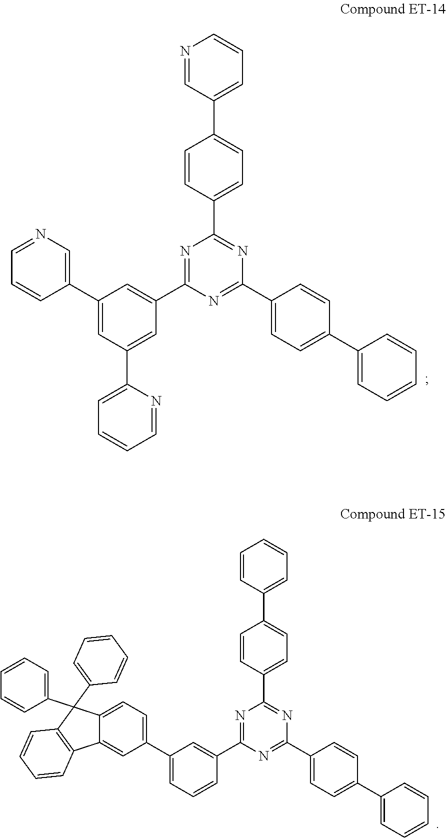 [SMILES: c1ccc(-c2ccc(-c3nc(-c4ccc(-c5cccnc5)cc4)nc(-c4cc(-c5cccnc5)cc(-c5ccccn5)c4)n3)cc2)cc1 ; c1ccc(-c2ccc(-c3nc(-c4ccc(-c5ccccc5)cc4)nc(-c4cccc(-c5ccc6c(c5)-c5ccccc5C6(c5ccccc5)c5ccccc5)c4)n3)cc2)cc1]

The compound ET-1 to the compound ET-15 all satisfy the general structural formula (I), and the electron transport layer is made of any one of materials having the above structures, so that the electron transport capability of the electron transport layer can be improved, and the electron transport is smoother.

A synthesis process of the compound ET-1 is shown as follows:

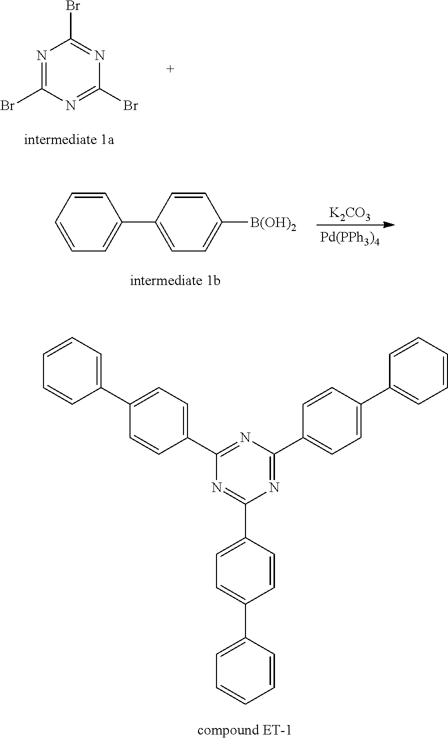

For example, an intermediate 1a (2-4-6-tribromotriazine) (6.3 g, 20 mmol) and an intermediate 1b (1-benzene-4-benzene borate) (9.2 g, 60 mmol) may be added in a flask to be reacted under catalysts Pd(PPh3)4 (0.7 g, 0.6 mmol) and K2CO3 (25 g, 200 mmol), and then be degassed with nitrogen. A heating reflux process is performed on the reacted mixture for 15 hours and the reacted mixture is then cooled to the room temperature. An extraction process is performed with dichloromethane and a drying process is performed with sodium sulfate on the cooled reacted mixture. Then after removal of the solvent, the coarse product is purified by using a column chromatographic method with dichloromethane to obtain a coarse product with a weight of 12.3 g. The coarse product is crystallized with hexane to obtain a pure product (with a yield of 75%) with a weight of 11.2 g. Thereafter, the structure of the product is confirmed by a chemical test method NMR and the purity of the product (purity of 99.3%) is confirmed by a chemical test method HPLC to finally confirm that the product is the compound ET-1.

It should be noted that (6.3 g, 20 mmol) represents that the intermediate 1a has a weight of 6.3 g, and 6.3 g is a weight of the intermediate 1a of 20 mmol. Similarly, (9.2 g, 60 mmol) represents that the intermediate 1b has a weight of 9.2 g, and 9.2 g is a weight of the intermediate 1b of 60 mmol.

A synthesis process for the compound ET-2 is shown as follows:

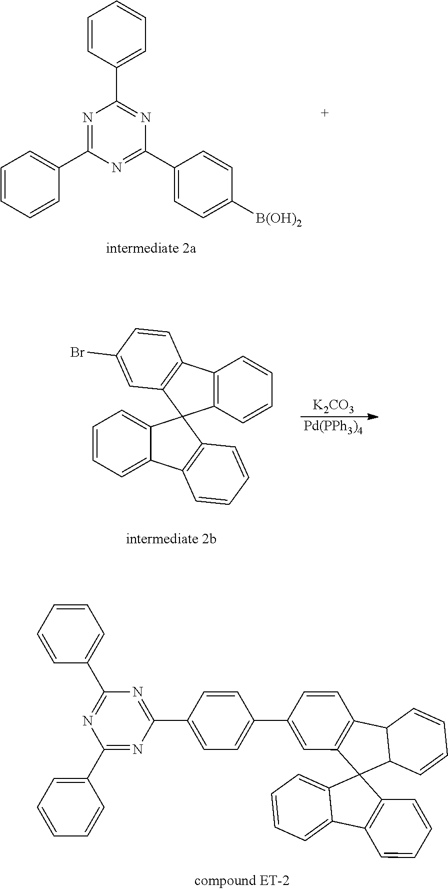

For example, an intermediate 2a (6.2 g, 20 mmol) and an intermediate 1b (7.9 g, 20 mmol) may be added in a flask to be reacted under catalysts Pd(PPh3)4 (0.7 g, 0.2 mmol) and K2CO3 (8 g, 70 mmol), and then degassed with nitrogen. A heating reflux process is performed on the reacted mixture for 15 hours and the reacted mixture is then cooled to the room temperature. An extraction process is performed with dichloromethane and a drying process is performed with sodium sulfate on the cooled reacted mixture. Then after removal of the solvent, the coarse product is purified by using a column chromatographic method with dichloromethane to obtain a coarse product with a weight of 11.1 g. The coarse product is crystallized with hexane to obtain a pure product (with a yield of 79%) with a weight of 9.8 g. Thereafter, the structure of the product is confirmed by a chemical test method NMR and the purity of the product (purity of 98.7%) is confirmed by a chemical test method HPLC to finally confirm that the product is the compound ET-2.

In order to provide a more comprehensive understanding of the light emitting device provided by the embodiments of the present disclosure, the light emitting device will be described in detail below as an overall example.

For example, as shown in FIG. 2, the thickness H1 of the first electron transport sub-unit 312 is less than the thickness H2 of the second electron transport sub-unit 322, which satisfies 50 Å(H2−H1)≤350 Å, so that the electron transport in the first light emitting unit 31 is smoother. Further, the thickness h(ETL1) of the first electron transport layer ETL1 is less than the thickness h(ETL2) of the second electron transport layer ETL2, which satisfies 50 Å≤h(ETL2)−h(ETL1)≤300 Å, further improving the smoothness of the electron transport in the first light emitting unit 31. Further, the LUMO levels of the N-type doped charge generation layer N-CGL and the first electron transport layer ETL1 are adjusted and controlled to satisfy 0.1 eV≤|LUMO(N-CGL)−LUMO(ETL1)|≤0.6 eV, further improving the smoothness of injecting electrons from the N-type doped charge generation layer N-CGL into the first electron transport layer ETL1, so as to improve the electron transport capability of the entire first light emitting unit 31. Furthermore, the material of the N-type doped charge generation layer N-CGL is doped with ytterbium Yb or lithium Li, the doping concentration of the ytterbium Yb or the lithium Li is larger than or equal to 1%, which improves the electron generation capability of the N-type doped charge generation layer N-CGL. Further, the LUMO levels of the first electron transport layer ETL1 and the first hole blocking layer HBL1 are adjusted and controlled to satisfy 0.1 eV≤|LUMO(HBL1)−LUMO(ETL1)|≤0.8 eV, and μₑ(ETL1)>μₑ(HBL1), further increasing the smoothness of injecting electrons from the first electron transport layer ETL1 into the first hole transport layer HTL1, to improve the electron transport capability of the first light emitting unit 31 as a whole. Further, the material of the first electron transport layer ETL1 is different from that of the second electron transport layer ETL2, and 0≤|LUMO(ETL1)−LUMO(ETL2)|≤0.4 eV is satisfied, thereby ensuring the smoothness of injecting electrons in the first light emitting unit 31. Further, the first electron transport layer ETL1 is made of the material having the azine unit so as to improve the electron transport capability of the first electron transport layer ETL1, so that the electron transport is smoother. The tandem light emitting device satisfying the above conditions improves the electron transport capability of the whole first light emitting unit 31, to balance the holes and electrons in the first light emitting layer EML1 and the second light emitting layer EML2, thereby improving the efficiency of the entire light emitting device.

In some implementations, the hole auxiliary layer may be made of a material having a specific group. Specifically, the general structural formulas of a material of the first hole auxiliary layer prime1 and a material of the second hole auxiliary layer prime2 are shown by the following structure (II):

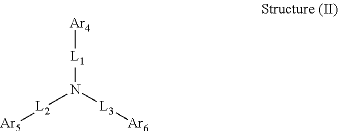

where, L₁, L₂ and L₃ each independently represent a connecting group and any one selected from a single bond, a substituted or unsubstituted C6 to C20 aryl group and a substituted or unsubstituted C5 to C20 heteroaryl group; Ar₄, Ar₅ and Ar₆ each independently represent any one selected from a C6 to C50 aryl group and a substituted or unsubstituted C5 to C50 heteroaryl group, a fluorene-based material, a dibenzo five-membered ring structure and adamantane.

Here, the first hole auxiliary layer prime1 and the second hole auxiliary layer prime2 are made of the material having the specific group, so that the first hole auxiliary layer prime1 and the second hole auxiliary layer prime2 each have good hole transport properties and properties of blocking excitons.

In some implementations, the structure of the fluorene-based material includes at least one of:

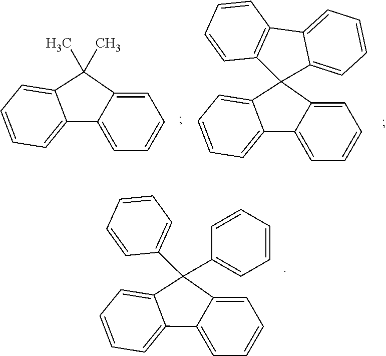

For example, the structure of each of the material of the first hole auxiliary layer prime1 containing the fluorene-based material and the material of the second hole auxiliary layer prime2 containing the fluorene-based material includes any one of:

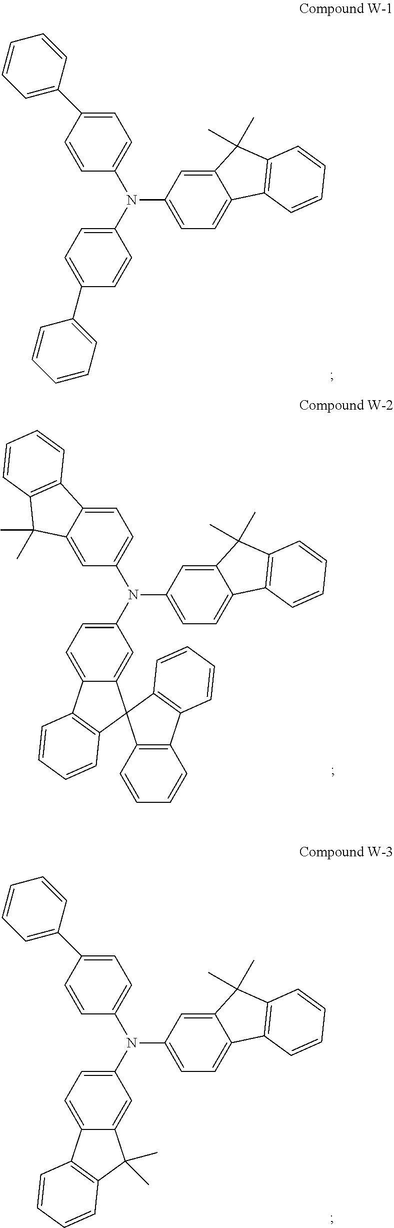 [SMILES: CC1(C)c2ccccc2-c2ccc(N(c3ccc(-c4ccccc4)cc3)c3ccc(-c4ccccc4)cc3)cc21 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C(C)(C)c3ccccc3-4)cc21]

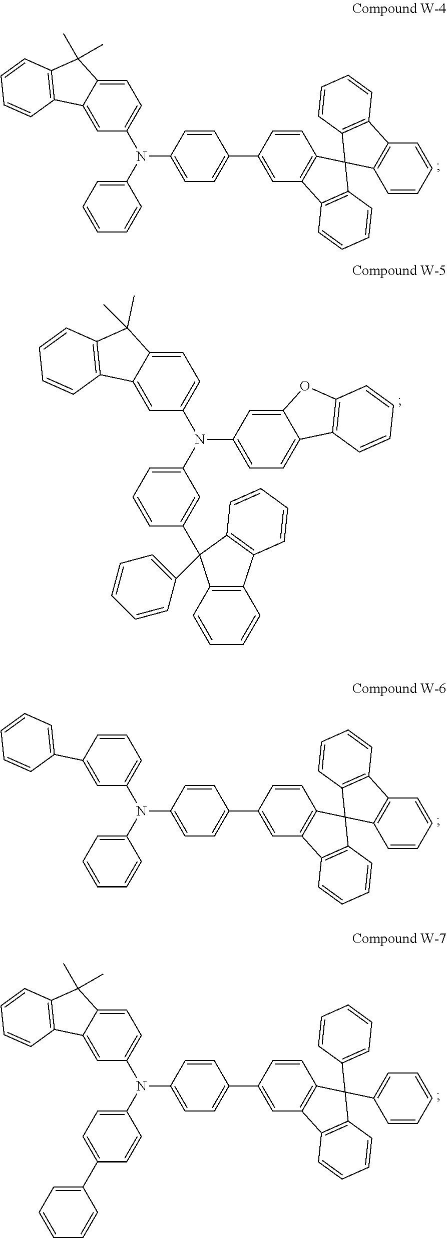 [SMILES: CC1(C)c2ccccc2-c2cc(N(c3ccccc3)c3ccc(-c4ccc5c(c4)-c4ccccc4C54c5ccccc5-c5ccccc54)cc3)ccc21 ; CC1(C)c2ccccc2-c2cc(N(c3cccc(C4(c5ccccc5)c5ccccc5-c5ccccc54)c3)c3ccc4c(c3)oc3ccccc34)ccc21 ; c1ccc(-c2cccc(N(c3ccccc3)c3ccc(-c4ccc5c(c4)-c4ccccc4C54c5ccccc5-c5ccccc54)cc3)c2)cc1 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21]

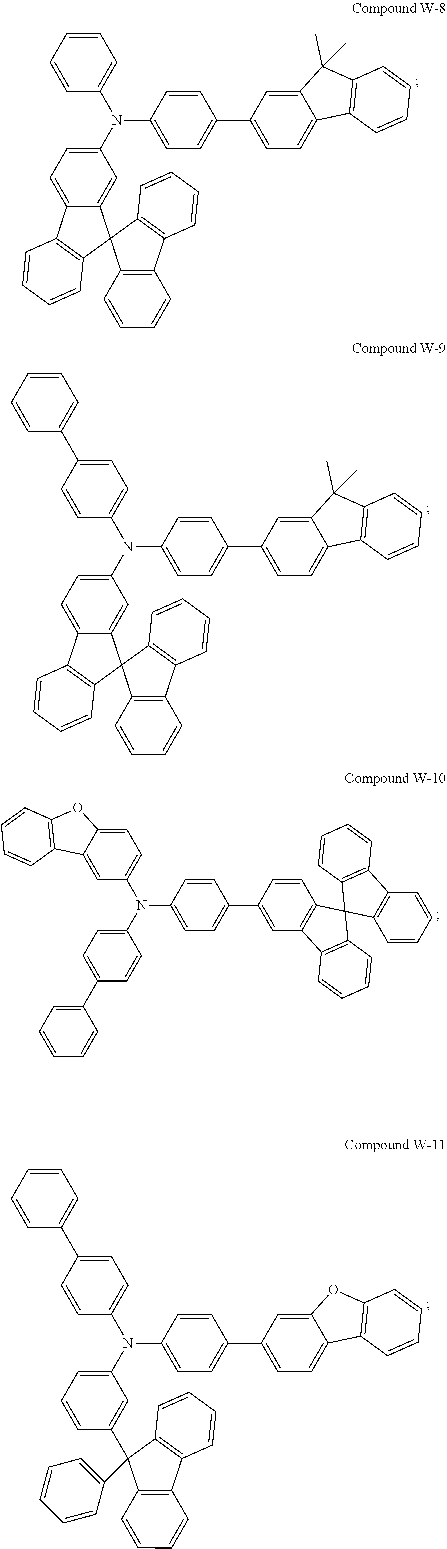 [SMILES: CC1(C)c2ccccc2-c2ccc(-c3ccc(N(c4ccccc4)c4ccc5c(c4)C4(c6ccccc6-c6ccccc64)c4ccccc4-5)cc3)cc21 ; CC1(C)c2ccccc2-c2ccc(-c3ccc(N(c4ccc(-c5ccccc5)cc4)c4ccc5c(c4)C4(c6ccccc6-c6ccccc64)c4ccccc4-5)cc3)cc21 ; c1ccc(-c2ccc(N(c3ccc(-c4ccc5c(c4)-c4ccccc4C54c5ccccc5-c5ccccc54)cc3)c3ccc4oc5ccccc5c4c3)cc2)cc1 ; c1ccc(-c2ccc(N(c3ccc(-c4ccc5c(c4)oc4ccccc45)cc3)c3cccc(C4(c5ccccc5)c5ccccc5-c5ccccc54)c3)cc2)cc1]

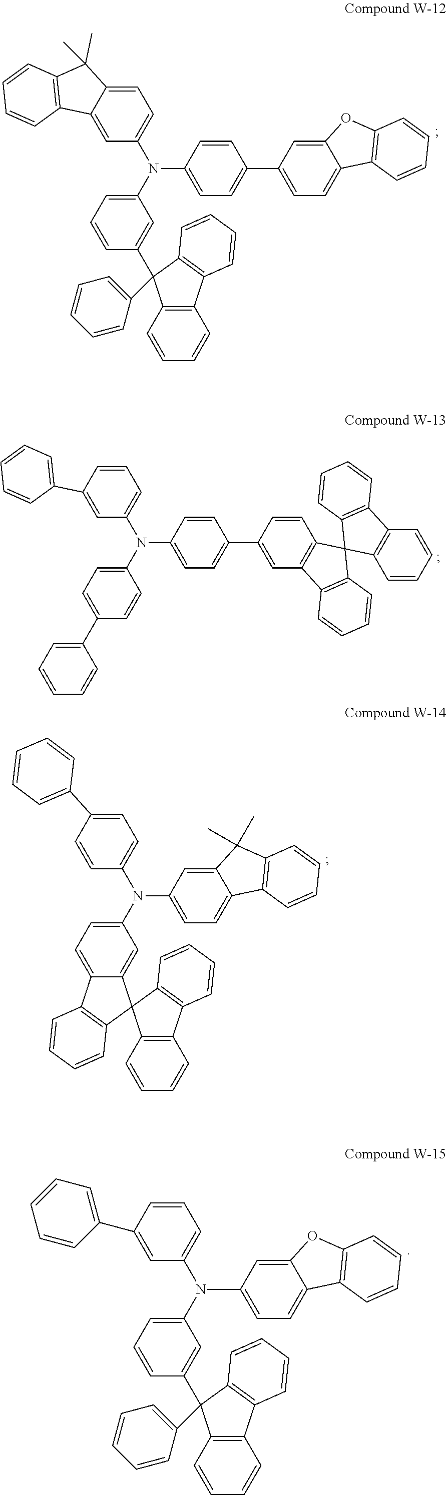

The compounds W-1 to W-15 each satisfy the general structural formula (II), any one of the above materials is selected as the material of the hole auxiliary layer, which can improve the hole transport capability of the hole auxiliary layer, so that the hole transport is smoother; and with combination of the selected material and the structure of the light emitting device the holes and electrons in the device are balanced, thereby improving the efficiency of the light emitting device.

A synthesis process of the compound W-1 is shown as follows:

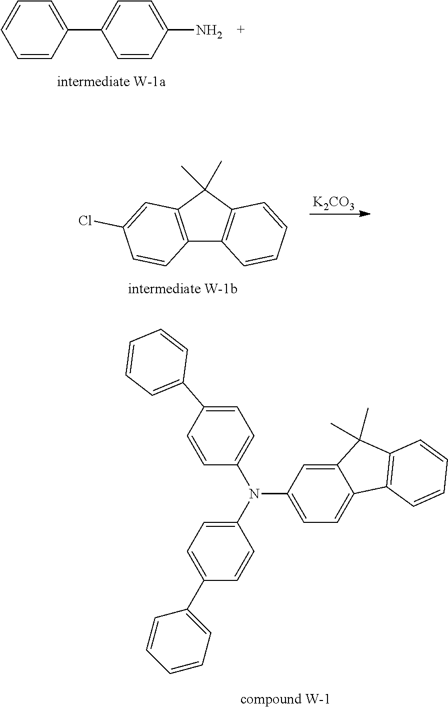

For example, an intermediate W-1a (2.0 g, 12 mmol), an intermediate W-1b (5.5 g, 24 mmol) and potassium carbonate (4.2 g, 30 mmol) are added into dimethylformamide (50 mL) and reacted by stirring and heating at 100° C. Water is added to the reaction solution to precipitate a solid, which is washed with methanol to obtain the compound W-1 (6.3 g, with a yield of 91% and a purity of 97.3%).

A synthesis process of the compound W-2 is shown as follows:

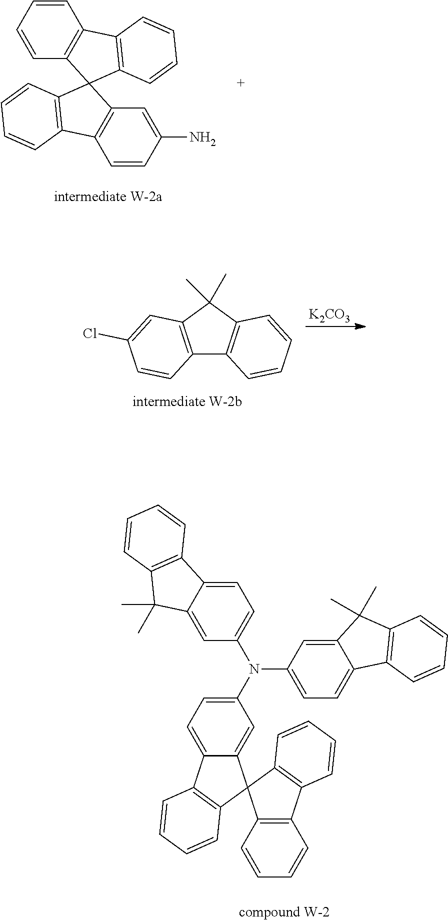

For example, an intermediate W-2a (4.0 g, 12 mmol), an intermediate W-2b (5.5 g, 24 mmol) and potassium carbonate (4.2 g, 30 mmol) are added into dimethylformamide (50 mL) and reacted by stirring and heating at 100° C. An obtained solid is washed with methanol to obtain the compound W-2 (8.1 g, with a yield of 91.0% and a purity of 97.1%).

In some implementations, the dibenzo five-membered ring structure includes:

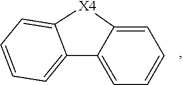

where, X4 is nitrogen N, oxygen O or sulfur S.

The dibenzo five-membered ring structure may be represented by DBX, where DB is dibenzo, X is a variable atom, and DBX may include carbazole, dibenzofuran, or dibenzothiophene, etc.

For example, the structures of the material of the first hole auxiliary layer prime1 containing the dibenzo five-membered ring structure and the material of the second hole auxiliary layer prime2 containing the dibenzo five-membered ring structure include any one of the following compounds:

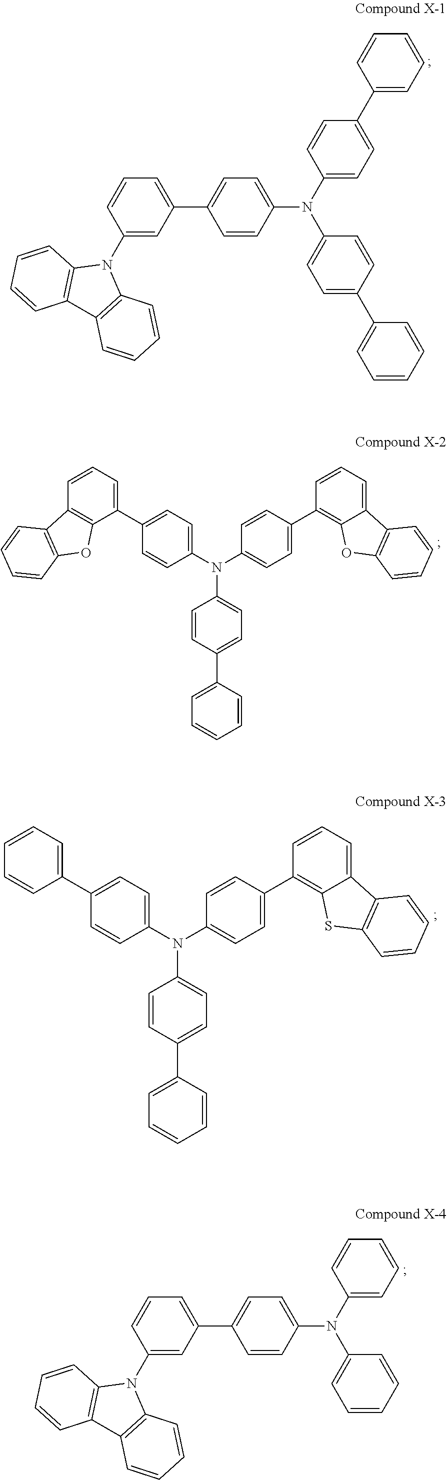 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccccc4)cc3)c3ccc(-c4cccc5c4sc4ccccc45)cc3)cc2)cc1 ; c1ccc(N(c2ccccc2)c2ccc(-c3cccc(-n4c5ccccc5c5ccccc54)c3)cc2)cc1]

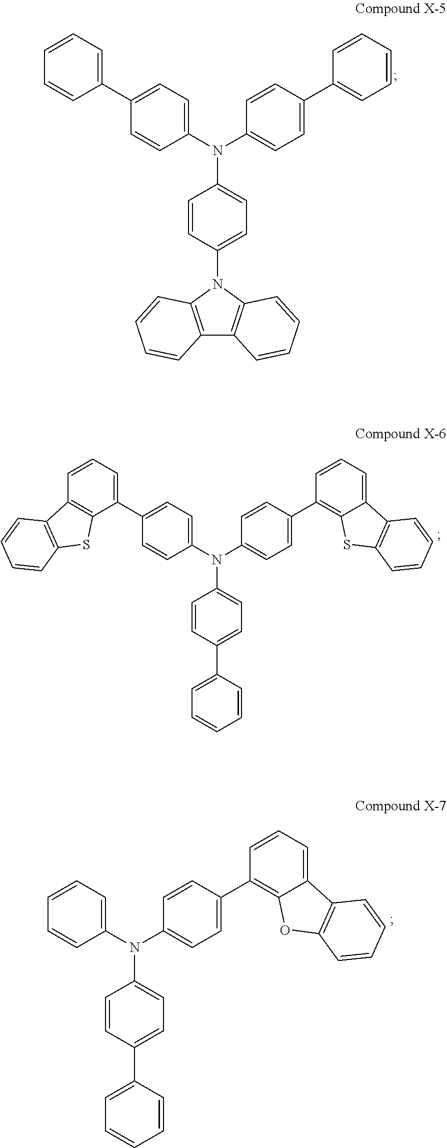 [SMILES: c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4cccc5c4sc4ccccc45)cc3)c3ccc(-c4cccc5c4sc4ccccc45)cc3)cc2)cc1 ; c1ccc(-c2ccc(N(c3ccccc3)c3ccc(-c4cccc5c4oc4ccccc45)cc3)cc2)cc1]

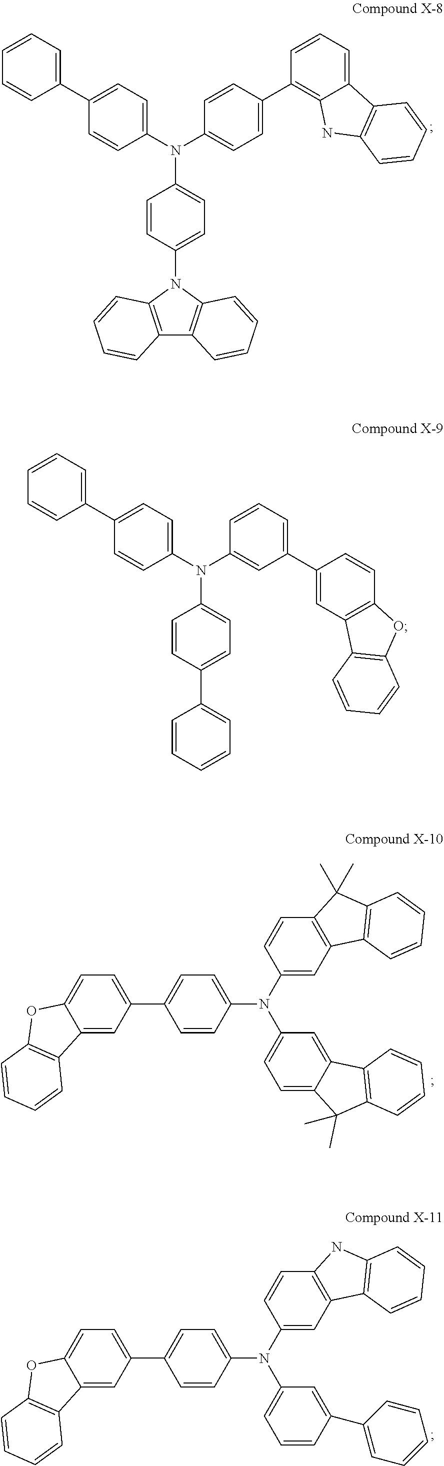 [SMILES: c1ccc(-c2ccc(N(c3ccc(-c4cccc5c4[nH]c4ccccc45)cc3)c3ccc(-n4c5ccccc5c5ccccc54)cc3)cc2)cc1 ; c1ccc(-c2ccc(N(c3ccc(-c4ccccc4)cc3)c3cccc(-c4ccc5oc6ccccc6c5c4)c3)cc2)cc1 ; CC1(C)c2ccccc2-c2cc(N(c3ccc(-c4ccc5oc6ccccc6c5c4)cc3)c3ccc4c(c3)-c3ccccc3C4(C)C)ccc21 ; c1ccc(-c2cccc(N(c3ccc(-c4ccc5oc6ccccc6c5c4)cc3)c3ccc4[nH]c5ccccc5c4c3)c2)cc1]

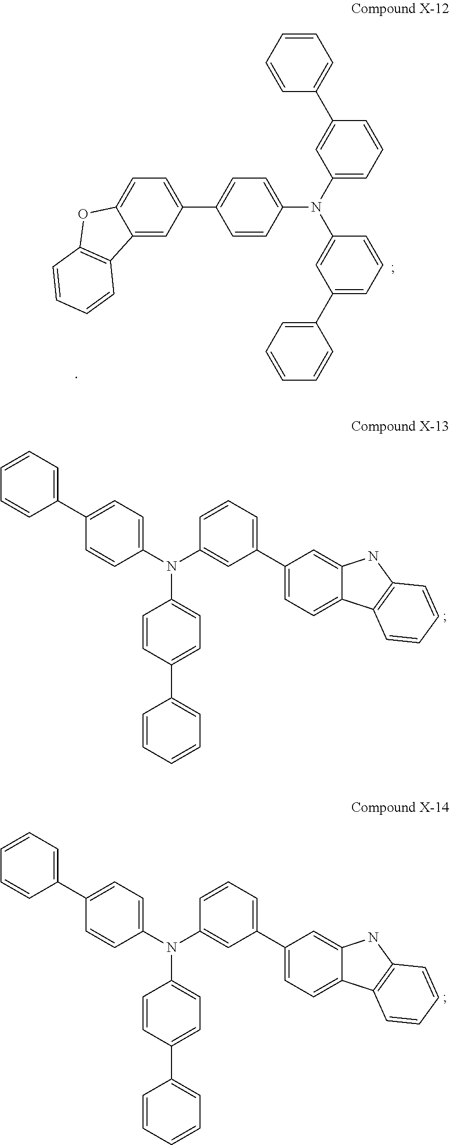 [SMILES: c1ccc(-c2cccc(N(c3ccc(-c4ccc5oc6ccccc6c5c4)cc3)c3cccc(-c4ccccc4)c3)c2)cc1 ; c1ccc(-c2ccc(N(c3ccc(-c4ccccc4)cc3)c3cccc(-c4ccc5c(c4)[nH]c4ccccc45)c3)cc2)cc1 ; c1ccc(-c2ccc(N(c3ccc(-c4ccccc4)cc3)c3cccc(-c4ccc5c(c4)[nH]c4ccccc45)c3)cc2)cc1]

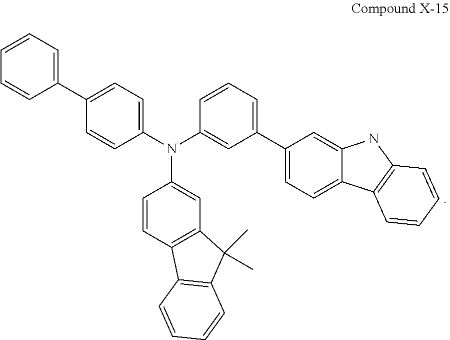 [SMILES: CC1(C)c2ccccc2-c2ccc(N(c3ccc(-c4ccccc4)cc3)c3cccc(-c4ccc5c(c4)[nH]c4ccccc45)c3)cc21]

The compounds X-1 to X-15 all satisfy the general structural formula (II), and any one of the above materials is selected as the material of the hole auxiliary layer, so that the triplet energy level T1 of the hole auxiliary layer can be increased, leakage of excitons of the light emitting layer (i.e., the first light emitting layer EML1 and/or the second light emitting layer EML2) is suppressed, and the efficiency of the light emitting device is improved.

A synthesis process of the compound X-1 is shown as follows:

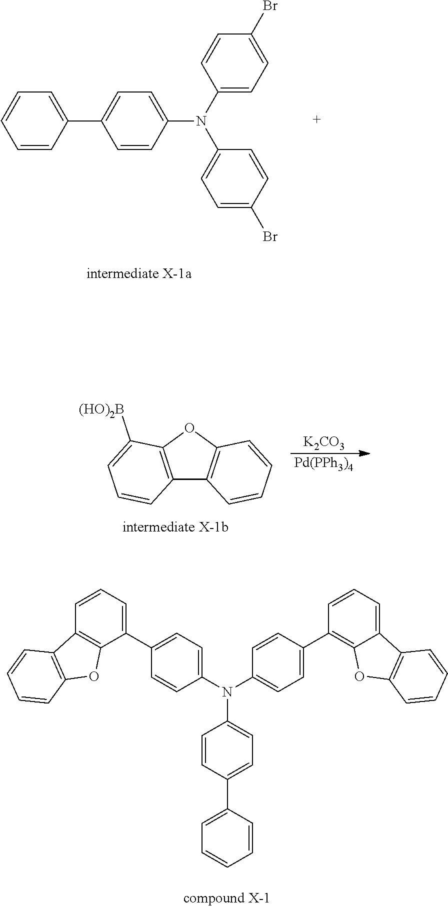

For example, an intermediate X-1a (5.7 g, 12 mmol), an intermediate X-1b (4.0 g, 24 mmol), tetrakis (triphenylphosphine) palladium (0.25 g, 0.24 mmol) and aqueous potassium carbonate (20 mL) are added into toluene (50 mL) and reacted by stirring and heating at 100° C. A solid is obtained by filtering, to obtain the compound X-1 (8.8 g, with a yield of 92.2% and a purity of 98.7%).

A synthesis process of the compound X-2 is shown as follows:

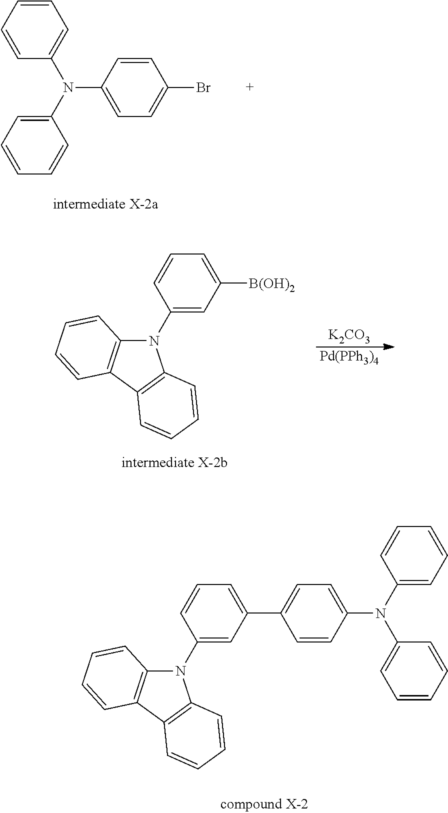 [SMILES: Brc1ccc(N(c2ccccc2)c2ccccc2)cc1 ; OB(O)c1cccc(-n2c3ccccc3c3ccccc32)c1 ; "K2CO3" ; c1ccc(N(c2ccccc2)c2ccc(-c3cccc(-n4c5ccccc5c5ccccc54)c3)cc2)cc1 ; "Pd(PPh3)4"]

For example, an intermediate X-2a (3.9 g, 12 mmol), an intermediate X-2b (2.9 g, 12 mmol), tetrakis (triphenylphosphine) palladium (0.14 g, 0.12 mmol) and aqueous potassium carbonate (20 mL) are added into toluene (50 mL) and reacted by stirring and heating at 100° C. A solid is obtained by filtering, to obtain the compound X-2 (6.1 g, with a yield of 90% and a purity of 98.1%).

In some implementations, a structure of the material of adamantane includes:

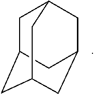

For example, the structures of the material of the first hole auxiliary layer prime1 containing the adamantane and the material of the second hole auxiliary layer prime2 containing the adamantane include any one of:

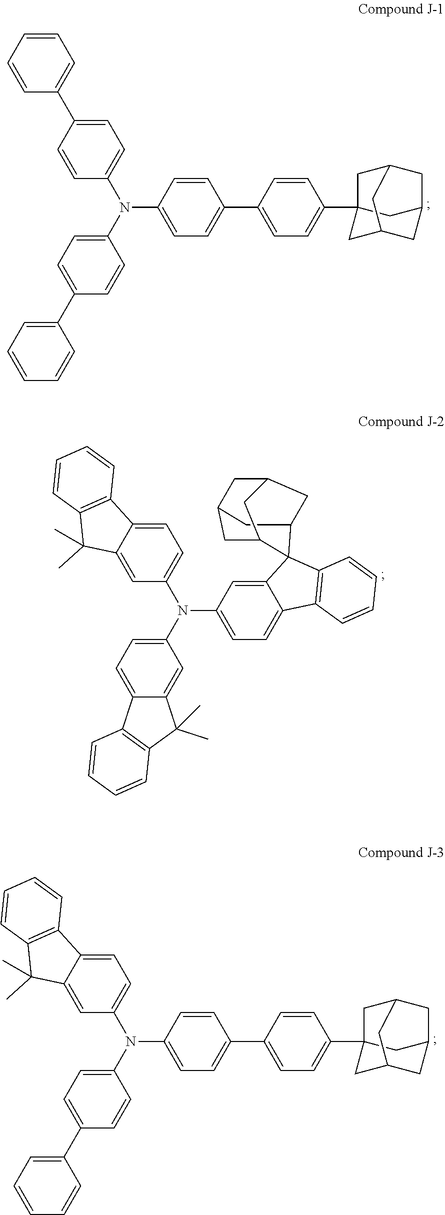 [SMILES: c1ccc(-c2ccc(N(c3ccc(-c4ccccc4)cc3)c3ccc(-c4ccc(C56CC7CC(CC(C7)C5)C6)cc4)cc3)cc2)cc1 ; CC1(C)c2ccccc2-c2ccc(N(c3ccc4c(c3)C(C)(C)c3ccccc3-4)c3ccc4c(c3)C3(c5ccccc5-4)C4CC5CC(C4)CC3C5)cc21 ; CC1(C)c2ccccc2-c2ccc(N(c3ccc(-c4ccccc4)cc3)c3ccc(-c4ccc(C56CC7CC(CC(C7)C5)C6)cc4)cc3)cc21]

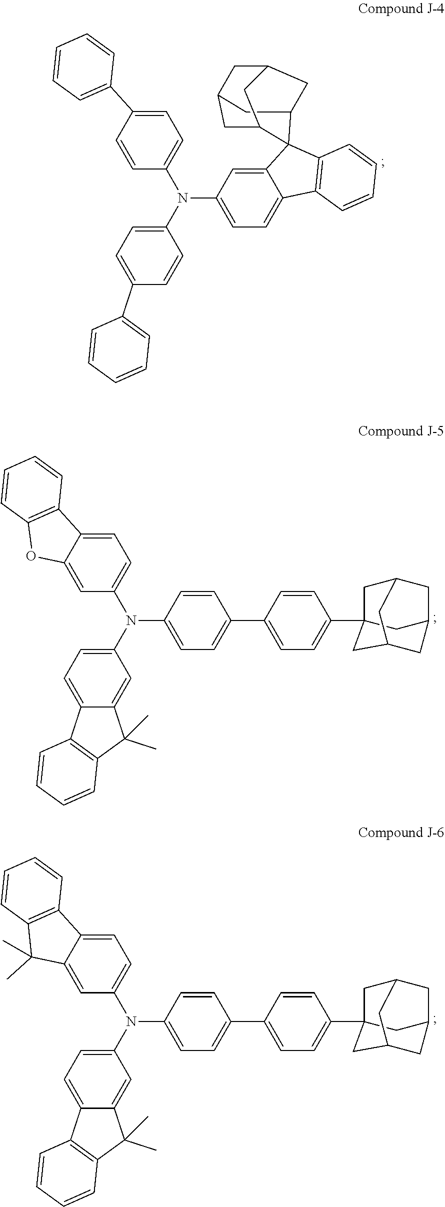 [SMILES: c1ccc(-c2ccc(N(c3ccc(-c4ccccc4)cc3)c3ccc4c(c3)C3(c5ccccc5-4)C4CC5CC(C4)CC3C5)cc2)cc1 ; CC1(C)c2ccccc2-c2ccc(N(c3ccc(-c4ccc(C56CC7CC(CC(C7)C5)C6)cc4)cc3)c3ccc4c(c3)oc3ccccc34)cc21 ; CC1(C)c2ccccc2-c2ccc(N(c3ccc(-c4ccc(C56CC7CC(CC(C7)C5)C6)cc4)cc3)c3ccc4c(c3)C(C)(C)c3ccccc3-4)cc21]

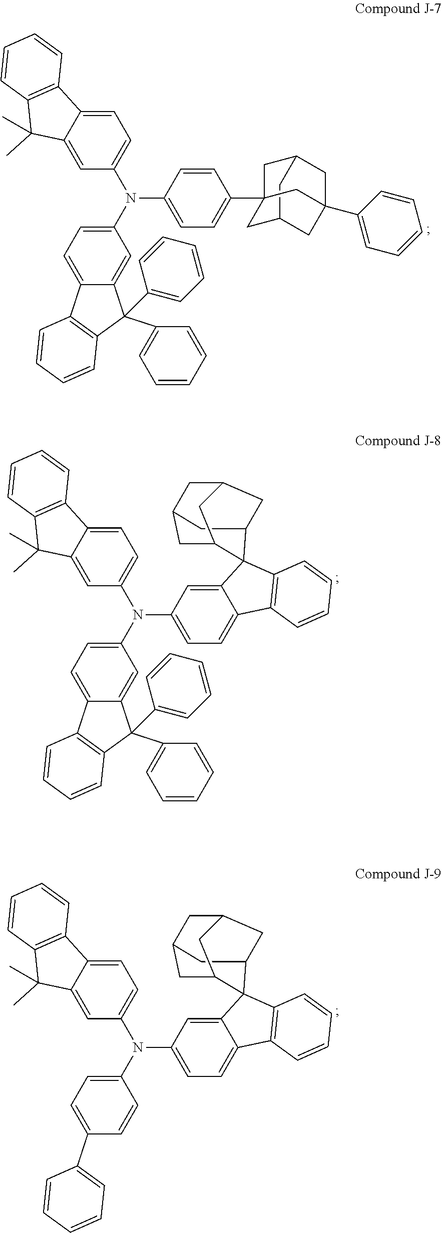 [SMILES: CC1(C)c2ccccc2-c2ccc(N(c3ccc(C45CC6CC(CC(c7ccccc7)(C6)C4)C5)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-4)C4CC5CC(C4)CC3C5)cc21 ; CC1(C)c2ccccc2-c2ccc(N(c3ccc(-c4ccccc4)cc3)c3ccc4c(c3)C3(c5ccccc5-4)C4CC5CC(C4)CC3C5)cc21]

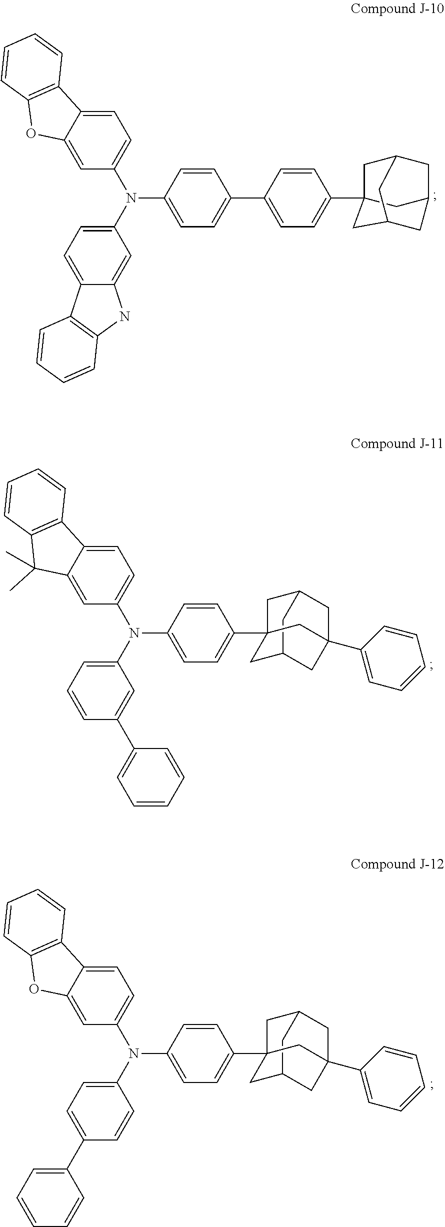 [SMILES: c1ccc2c(c1)[nH]c1cc(N(c3ccc(-c4ccc(C56CC7CC(CC(C7)C5)C6)cc4)cc3)c3ccc4c(c3)oc3ccccc34)ccc12 ; CC1(C)c2ccccc2-c2ccc(N(c3ccc(C45CC6CC(CC(c7ccccc7)(C6)C4)C5)cc3)c3cccc(-c4ccccc4)c3)cc21 ; c1ccc(-c2ccc(N(c3ccc(C45CC6CC(CC(c7ccccc7)(C6)C4)C5)cc3)c3ccc4c(c3)oc3ccccc34)cc2)cc1]

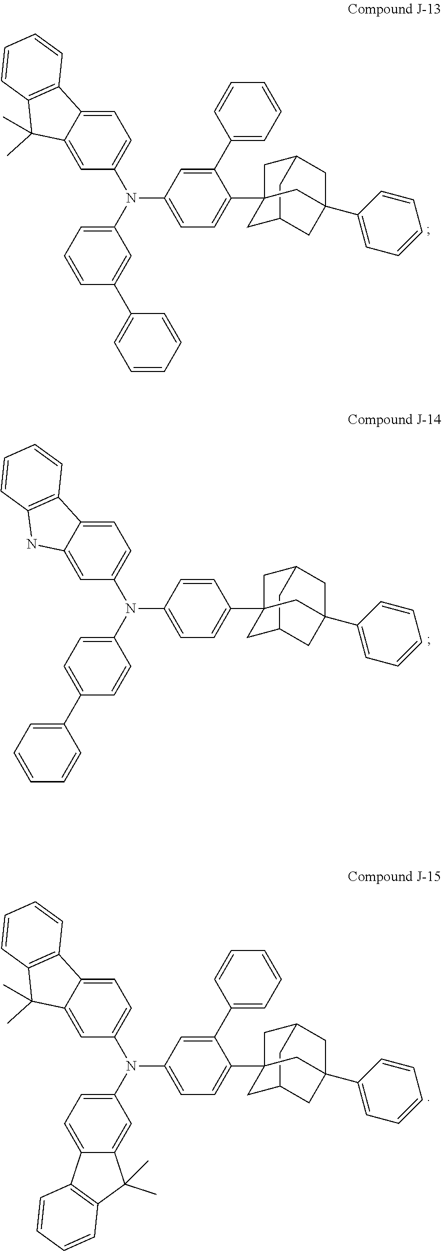 [SMILES: CC1(C)c2ccccc2-c2ccc(N(c3cccc(-c4ccccc4)c3)c3ccc(C45CC6CC(CC(c7ccccc7)(C6)C4)C5)c(-c4ccccc4)c3)cc21 ; c1ccc(-c2ccc(N(c3ccc(C45CC6CC(CC(c7ccccc7)(C6)C4)C5)cc3)c3ccc4c(c3)[nH]c3ccccc34)cc2)cc1 ; CC1(C)c2ccccc2-c2ccc(N(c3ccc(C45CC6CC(CC(c7ccccc7)(C6)C4)C5)c(-c4ccccc4)c3)c3ccc4c(c3)C(C)(C)c3ccccc3-4)cc21]

The compounds J-1 to J-15 all satisfy the structural general formula (II), and any one of the above materials is selected as the material of the hole auxiliary layer, so that the structural three-dimensional structure of the material of the hole auxiliary layer can be increased, the film forming property of the film is better, and the crystallization is reduced.

A synthesis process of the compound J-1 is shown as follows:

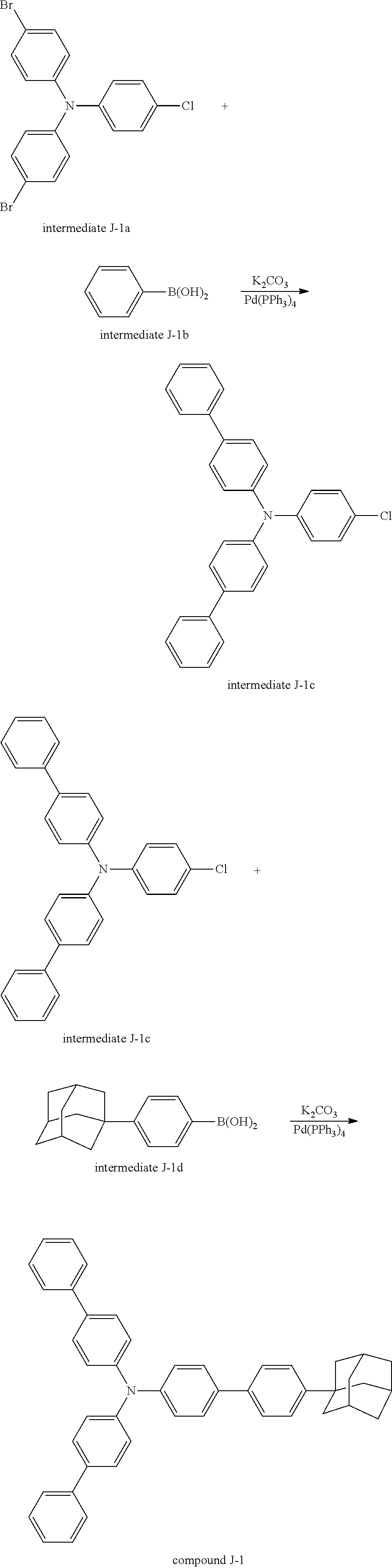

For example, under an argon atmosphere, an intermediate J-1a (4.4 g, 10 mmol), an intermediate J-1b (1.5 g, 20 mmol), tetrakis (triphenylphosphine) palladium (0.21 g, 0.2 mmol) and aqueous potassium carbonate (20 mL) are added into toluene (50 mL) and reacted by stirring and heating at 80° C. for 8 hours. The sample obtained by separating and filtering is purified by using a silica gel column chromatographic method to obtain an intermediate J-1c (4.8 g, with a yield of 81%). Next, under an argon atmosphere, the intermediate J-1c (3.4 g, 8 mmol), an intermediate J-1d (1.7 g, 8 mmol), tetrakis (triphenylphosphine) palladium (0.11 g, 0.1 mmol) and aqueous potassium carbonate (20 mL) are added into toluene (50 mL) and reacted by stirring and heating at 80° C. for 8 hours. The sample obtained by separating and filtering is purified by using the silica gel column chromatographic method to obtain the compound J-1 (4.7 g, with a yield of 91% and a purity of 98.9%).

A synthesis process of the compound J-2 is shown as follows:

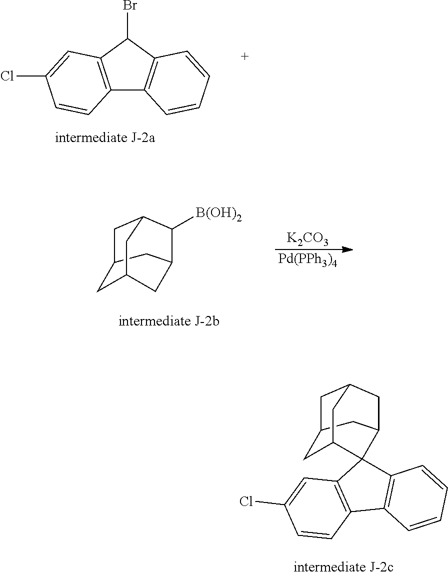

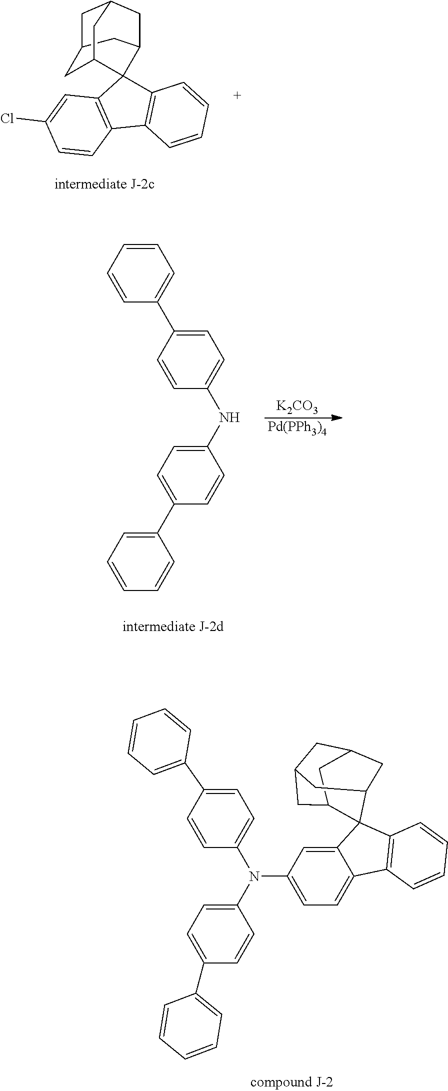

For example, under an argon atmosphere, an intermediate J-2a (5.6 g, 20 mmol), an intermediate J-1b (2.7 g, 20 mmol), tetrakis (triphenylphosphine) palladium (0.21 g, 0.2 mmol) and aqueous potassium carbonate (20 mL) are added into toluene (50 mL) and reacted by stirring and heating at 80° C. for 8 hours. An intermediate J-2c (4.7 g, with a yield of 82%) is obtained by filtering. Next, under an argon atmosphere, the intermediate J-2c (3.8 g, 12 mmol), an intermediate J-2d (3.8 g, 12 mmol), and potassium carbonate (3.8 g, 20 mmol) are added into dimethylformamide (40 mL) and reacted by stirring and heating at 100° C. Water is added into the reaction solution to precipitate a solid, which is washed with methanol to obtain the compound J-2 (6.4 g, with a yield of 85% and a purity of 96.2%).

In some implementations, the structures of the materials for other functional layers in the light emitting device, such as the hole injection layer HIL, the hole transport layer HTL, the hole blocking layer HBL, are as follows:
the structure of the material of the hole injection layer HIL is:

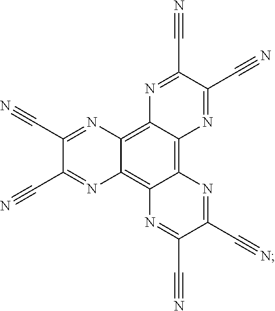 [SMILES: N#Cc1nc2c3nc(C#N)c(C#N)nc3c3nc(C#N)c(C#N)nc3c2nc1C#N]

the structure of the material of the hole transport layer HTL is:

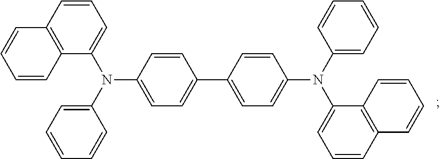 [SMILES: c1ccc(N(c2ccc(-c3ccc(N(c4ccccc4)c4cccc5ccccc45)cc3)cc2)c2cccc3ccccc23)cc1]

the structure of the material of the hole blocking layer HBL is:

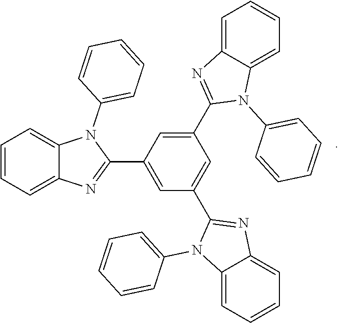 [SMILES: c1ccc(-n2c(-c3cc(-c4nc5ccccc5n4-c4ccccc4)cc(-c4nc5ccccc5n4-c4ccccc4)c3)nc3ccccc32)cc1]

The material of the electron injection layer may be Yb. The material of the anode 1 may be ITO. The material of the cathode 2 may be Mg: Ag, which means that Ag is doped in Mg.

In some implementations, the light emitting device may be a red light emitting device 01, and the first light emitting layer EML1 and/or the second light emitting layer EML2 in the light emitting device are red light emitting layers EML-R.

For example, the material of the red light emitting layer EML-R includes a red host material RH and a red guest material RD, where the red host material RH includes an N-type doped red host material RH-N and a P-type doped red host material RH-P.

A structure of the N-type doped red host material RH-N is as follows:

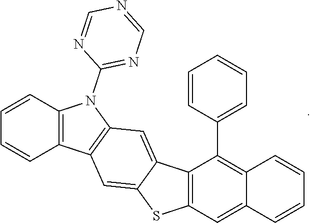 [SMILES: c1ccc(-c2c3ccccc3cc3sc4cc5c6ccccc6n(-c6ncncn6)c5cc4c23)cc1]

A structure of the P-type doped red host material RH-P is as follows:

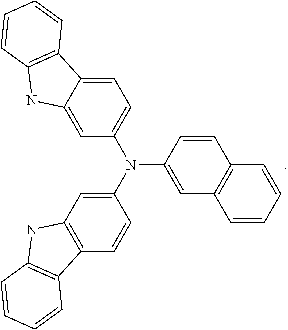 [SMILES: c1ccc2cc(N(c3ccc4c(c3)[nH]c3ccccc34)c3ccc4c(c3)[nH]c3ccccc34)ccc2c1]

A structure of the red guest material RD is as follows:

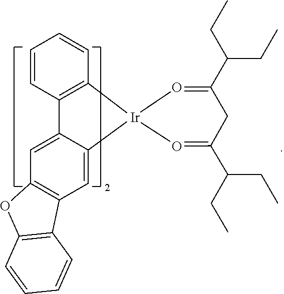

In some implementations, the light emitting device may be a green light emitting device 02, and the first light emitting layer EML1 and/or the second light emitting layer EML2 in the light emitting device are green light emitting layers EML-G.

For example, the material of the green light emitting layer EML-G includes a green host material GH and a green guest material GD, where the green host material GH includes an N-type doped green host material GH-N and a P-type doped green host material GH-P.

A structure of the N-type doped green host material GH-N is as follows:

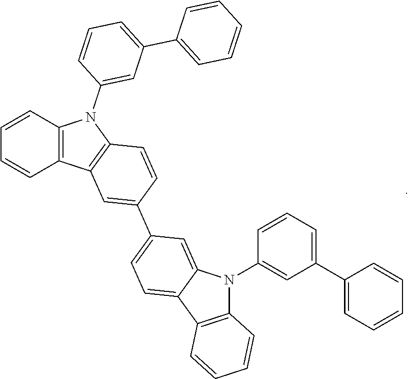 [SMILES: c1ccc(-c2cccc(-n3c4ccccc4c4cc(-c5ccc6c7ccccc7n(-c7cccc(-c8ccccc8)c7)c6c5)ccc43)c2)cc1]

A structure of the P-type doped green host material GH-P is as follows:

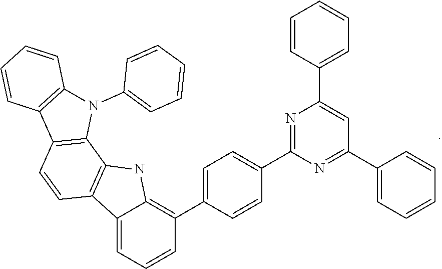 [SMILES: c1ccc(-c2cc(-c3ccccc3)nc(-c3ccc(-c4cccc5c4[nH]c4c5ccc5c6ccccc6n(-c6ccccc6)c54)cc3)n2)cc1]

A structure of the green guest material GD is as follows:

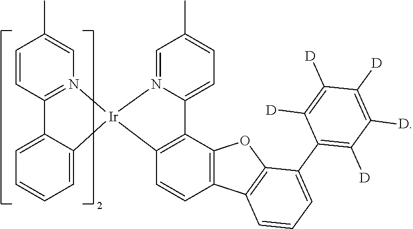

In some implementations, the light emitting device may be a blue light emitting device 03, and the first light emitting layer EML1 and/or the second light emitting layer EML2 in the light emitting device are blue light emitting layers EML-B.

For example, the material of the blue light emitting layer EML-B includes a blue host material BH and a blue guest material BD.

A structure of the blue host material BH is as follows:

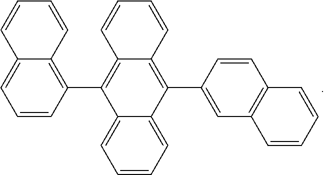 [SMILES: c1ccc2cc(-c3c4ccccc4c(-c4cccc5ccccc45)c4ccccc34)ccc2c1]

A structure of the blue guest material BD is as follows:

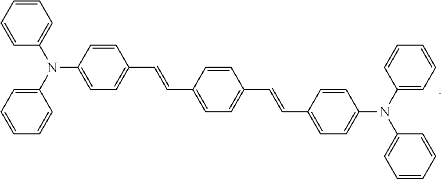 [SMILES: C(=C\c1ccc(N(c2ccccc2)c2ccccc2)cc1)/c1ccc(/C=C/c2ccc(N(c3ccccc3)c3ccccc3)cc2)cc1]

The above is a detailed description of the structure of the light emitting device.

In addition, in order to obtain a more comprehensive understanding of the performance of the light emitting device provided by the embodiments of the present disclosure, performance parameters of the light emitting device provided by the present disclosure and the existing light emitting device are described below through comparison in an overall example.

The light emitting device is the blue light emitting device 03, a structure of a material of the electron transport layer ET-T in the blue light emitting device 03 provided in a comparative example Q is as follows:

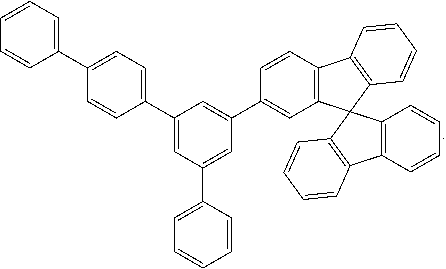 [SMILES: c1ccc(-c2ccc(-c3cc(-c4ccccc4)cc(-c4ccc5c(c4)C4(c6ccccc6-c6ccccc64)c4ccccc4-5)c3)cc2)cc1]

A structure of a material of the hole auxiliary layer prime-B′-T in the blue light emitting device 03 provided in the comparative example Q is as follows:

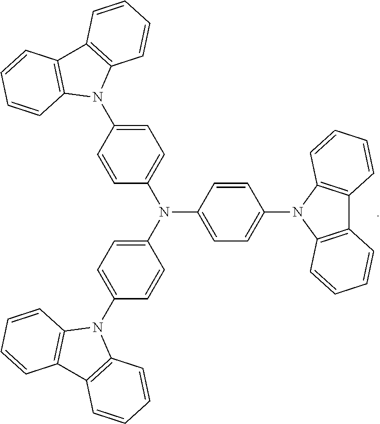 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

It should be noted that the hole auxiliary layer prime includes a first hole auxiliary layer prime1 and an auxiliary layer prime2. The electron transport layer ETL includes a first electron transport layer ETL1 and a second electron transport layer ETL2. The hole blocking layer HBL includes a first hole blocking layer HBL1 and a second hole blocking layer HBL2.

In a first implementation, a case where the blue light emitting device 03 includes one first light emitting unit 31 and one second light emitting unit 32 is taken as an example. As shown in FIG. 2, the materials of the first electron transport layer ETL1 and the second electron transport layer ETL2 in the blue light emitting device 03 are the same. Parameters, including the LUMO level and the electron mobility, of the electron transport layer ETL are shown in table 1.

TABLE 1

| Material | LUMO level (eV) | Electron mobility (cm²/(V · s) ) |
|---|---|---|
| Compound ET-1 | −2.99 | 3.6 × 10⁻⁶ |
| Compound ET-2 | −3.14 | 9.3 × 10⁻⁶ |
| Compound ET-3 | −3.23 | 3.4 × 10⁻⁵ |
| Compound ET-4 | −2.96 | 1.6 × 10⁻⁵ |
| Compound ET-5 | −3.01 | 6.9 × 10⁻⁶ |
| Comparative | −2.68 | 7.9 × 10⁻⁷ |
| example ET-T | | |

In addition, in this implementation, the LUMO level of the hole blocking layer HBL is −2.79 eV, and the electron mobility of the hole blocking layer HBL is 8.6×10⁻⁷ cm²/(V·s). The LUMO level of the N-type doped charge generation layer N-CGL is −2.97 eV; thicknesses of the first hole blocking layer HBL1 and the second hole blocking layer HBL2 each are 50 Å; a thickness of the first electron transport layer ETL1 is 50 Å, a thickness of the second electron transport layer ETL2 is 300 Å, and a thickness of the N-type doped charge generation layer N-CGL is 180 Å.

For the preparation of a blue light emitting device 03D1, specifically, a first hole injection layer HIL1, a first hole transport layer HTL1, a first hole auxiliary layer prime1-B′, a first light emitting layer EML1-B (BH: BD (2%)), a first hole blocking layer HBL1, a first electron transport layer ETL1 (made of the compound ET-1), an N-type doped charge generation layer N-CGL, a P-type doped charge generation layer P-CGL, a second hole transport layer HTL2, a second hole auxiliary layer prime 2-B′, a second light emitting layer EML2-B (BH: BD (2%)), a second hole blocking layer HBL2, a second electron transport layer ETL2 (made of the compound ET-1), a second electron injection layer EIL2, and a cathode 2 are sequentially evaporated on an ITO base substrate. A thickness of the first hole injection layer HIL1 is 10 nm, a thickness of the first hole transport layer HTL1 is 20 nm, a thickness of the first hole auxiliary layer prime1-B′ is 10 nm, a thickness of the first light emitting layer EML1-B is 20 nm, a thickness of the first hole blocking layer HBL1 is 5 nm, a thickness of the first electron transport layer ETL1 is 5 nm, a thickness of the N-type doped charge generation layer N-CGL is 18 nm, a thickness of the P-type doped charge generation layer P-CGL is 90 nm, a thickness of the second hole transport layer HTL2 is 40 nm, a thickness of the second hole auxiliary layer prime2-B′ is 10 nm, a thickness of the second light emitting layer EML2-B is 20 nm, a thickness of the second hole blocking layer HBL2 is 5 nm, a thickness of the second electron transport layer ETL2 is 30 nm, a thickness of the second electron injection layer EIL2 is 1 nm, and a thickness of the cathode is 13 nm.

It should be noted that BH: BD (2%) indicates that the blue host material BH is doped with the blue guest material BD with a doping concentration of 2%.

For the preparation of a blue light emitting device 03D2: the material of the electron transport layer ETL is replaced by the compound ET-2, and other structures are unchanged.

For the preparation of a blue light emitting device 03D3: the material of the electron transport layer ETL is replaced by the compound ET-3, and other structures are unchanged.

For the preparation of a blue light emitting device 03D4: the material of the electron transport layer ETL is replaced by the compound ET-4, and other structures are unchanged.

For the preparation of the blue light emitting device 03DT-1 in the comparative example: the material of the electron transport layer ETL is replaced by the compound ET-T, the material of the hole auxiliary layer prime is replaced by the material prime-B′-T, and other structures are unchanged.

The blue light emitting device 03 is tested for voltage, efficiency and service life according to the above structures, and the specific data results are shown in the table 2.

TABLE 2

| Light emitting | | | | |
|---|---|---|---|---|
| device | ETL1 and ETL2 | Voltage | Efficiency | Service life |
| D1 | Compound ET-1 | 95% | 120% | 121% |
| D2 | Compound ET-2 | 96% | 112% | 141% |
| D3 | Compound ET-3 | 96% | 109% | 179% |
| D4 | Compound ET-4 | 95% | 116% | 156% |
| DT-1 | Compound ET-T | 100% | 100% | 100% |

It can be seen from above that in a case where the material of the first electron transport layer ETL1 provided in the embodiments of the present disclosure is selected and both the LUMO level of the first hole blocking layer HBL1 and the LUMO level of the N-type doped charge generation layer N-CGL are satisfied, the electron transport property of the material of the first electron transport layer ETL1 itself is improved and the LUMO level of the first hole blocking layer HBL1 and the LUMO level of the N-type doped charge generation layer N-CGL are matched, so that electrons can be smoothly transported from the N-type doped charge generation layer N-CGL to the first light emitting layer EML1, thereby greatly improving the service life and efficiency of the light emitting device.

In a second implementation, a case where the blue light emitting device 03 includes one first light emitting unit 31 and one second light emitting unit 32 is taken as an example. As shown in FIG. 2, the materials of the first electron transport layer ETL1 and the second electron transport layer ETL2 in the blue light emitting device 03 are different. In this implementation, a case where the compound ET-2, the compound ET-3, and the compound ET-4 are respectively selected as the material of the first electron transport layer ETL1, and the compound ET-1 is selected as the material of the second electron transport layer ETL2 as a example.

In this implementation, the LUMO level of the hole blocking layer HBL is −2.79 eV, and the electron mobility of the hole blocking layer HBL is 8.6×10⁻⁷ cm²/(V·s). The LUMO level of the N-type doped charge generation layer N-CGL is −2.97 eV; thicknesses of the first hole blocking layer HBL1 and the second hole blocking layer HBL2 each are 50 Å; a thickness of the first electron transport layer ETL1 is 50 Å, a thickness of the second electron transport layer ETL2 is 300 Å, and a thickness of the N-type doped charge generation layer N-CGL is 180 Å.

For the preparation of a blue light emitting device 03D5, specifically, a first hole injection layer HIL1, a first hole auxiliary layer prime1-B′, a first light emitting layer EML1-B (BH: BD (2%)), a first hole blocking layer HBL1, a first electron transport layer ETL1 (made of the compound ET-1), an N-type doped charge generation layer N-CGL, a P-type doped charge generation layer P-CGL, a second hole transport layer HTL2, a second hole auxiliary layer prime2-B′, a second light emitting layer EML2-B (BH: BD (2%)), a second hole blocking layer HBL2, a second electron transport layer ETL2 (made of the compound ET-1), a second electron injection layer EIL2 and a cathode 2 are sequentially evaporated on an ITO base substrate. A thickness of the first hole injection layer HIL1 is 10 nm, a thickness of the first hole transport layer HTL1 is 20 nm, a thickness of the first hole auxiliary layer prime1-B′ is 10 nm, a thickness of the first light emitting layer EML1-B is 20 nm, a thickness of the first hole blocking layer HBL1 is 5 nm, a thickness of the first electron transport layer ETL1 is 5 nm, a thickness of the N-type doped charge generation layer N-CGL is 18 nm, a thickness of the P-type doped charge generation layer P-CGL is 90 nm, a thickness of the second hole transport layer HTL2 is 40 nm, a thickness of the second hole auxiliary layer prime2-B′ is 10 nm, a thickness of the second light emitting layer EML2-B is 20 nm, a thickness of the second hole blocking layer HBL2 is 5 nm, a thickness of the second electron transport layer ETL2 is 30 nm, a thickness of the second electron injection layer EIL2 is 1 nm, and a thickness of the cathode is 13 nm.

For the preparation of a blue light emitting device 03D6: the material of the electron transport layer ETL is replaced by the compound ET-3, and other structures are unchanged.

For the preparation of a blue light emitting device 03D7: the material of the electron transport layer ETL is replaced by the compound ET-4, and other structures are unchanged.

For the preparation of a blue light emitting device 03DT-2 in the comparative example: the material of the first electron transport layer ETL1 is replaced by the compound ET-T, the material of the second electron transport layer ETL2 is replaced by the compound ET-1, the material of the hole auxiliary layer prime is replaced by the material prime-B′-T, and other structures are unchanged.

The blue light emitting device 03 is tested for voltage, efficiency and life according to the above structures, and the specific data results are as shown in table 3.

TABLE 3

| Light emitting device | ETL1 | ETL2 | Voltage | Efficiency | Service life |
|---|---|---|---|---|---|
| D5 | ET-2 | ET-1 | 99% | 109% | 110% |
| D6 | ET-3 | ET-1 | 97% | 106% | 137% |
| D7 | ET-4 | ET-1 | 97% | 107% | 114% |
| DT-2 | ET-T | ET-1 | 100% | 100% | 100% |

It can be seen from above that in a case where the materials of the first electron transport layer ETL1 and the second electron transport layer ETL2 provided in the embodiments of the present disclosure are selected, the LUMO level of the first electron transport layer ETL1 and the LUMO level of the first hole blocking layer HBL1 are matched, and the LUMO level of the first hole blocking layer HBL1 and the LUMO level of the N-type doped charge generation layer N-CGL are matched, so that electrons can be smoothly transported from the N-type doped charge generation layer N-CGL to the first light emitting layer EML1, thereby greatly improving the service life and efficiency of the light emitting device.

An embodiment of the present disclosure further provides a display panel, including the light emitting device of any one of the above embodiments.

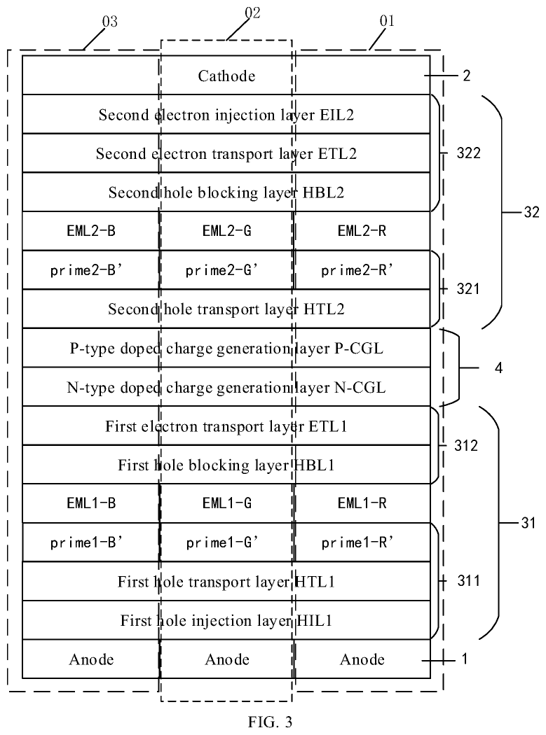

In some implementations, FIG. 3 is a schematic diagram of a display panel according to the embodiment of the present disclosure; as shown in FIG. 3, the display panel includes a red light emitting device 01, a green light emitting device 02, and a blue light emitting device 03. A thickness of the first hole auxiliary layer prime1-R′ of the red light emitting device 01 is greater than that of the first hole auxiliary layer prime1-G′ of the green light emitting device 02, and a thickness of the first hole auxiliary layer prime1-G′ of the green light emitting device 02 is greater than that of the first hole auxiliary layer prime1-B′ of the blue light emitting device 03; a thickness of the second hole auxiliary layer prime2-R′ of the red light emitting device 01 is greater than a thickness of the second hole auxiliary layer prime2-G′ of the green light emitting device 02, and a thickness of the second hole auxiliary layer prime2-G′ of the green light emitting device 02 is greater than a thickness of the second hole auxiliary layer prime2-B′ of the blue light emitting device 03.

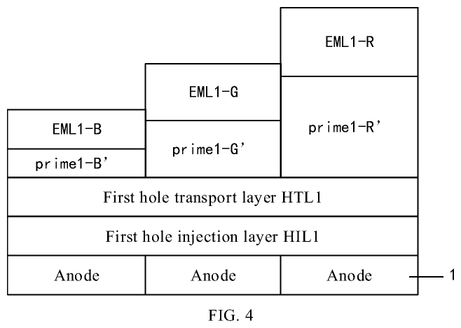

For example, the thicknesses of the first and second hole auxiliary layers prime1-R′ and prime2-R′ of the red light emitting device 01 are the same, and the thickness of the first hole auxiliary layer prime1-R′ of the red light emitting device 01 is between 25 nm and 30 nm. For example, as shown in FIG. 4, the thicknesses of the first hole auxiliary layer prime1-R′ and the second hole auxiliary layer prime 2-R′ of the red light emitting device 01 are 27 nm.

For example, the thicknesses of the first hole auxiliary layer prime1-G′ and the second hole auxiliary layer prime2-G′ of the green light emitting device 02 are the same, and the thickness of the first hole auxiliary layer prime1-G′ of the green light emitting device 02 is between 8 nm and 17 nm. For example, as shown in FIG. 4, the thicknesses of the first hole auxiliary layer prime1-G′ and the second hole auxiliary layer prime2-G′ of the green light emitting device 02 are 15 nm.

For example, the thicknesses of the first and second hole auxiliary layers prime1-B′ and prime2-B′ of the blue light emitting device 03 are the same, and the thickness of the first hole auxiliary layer prime1-B′ of the blue light emitting device 03 is between 8 nm and 13 nm. For example, as shown in FIG. 4, the thicknesses of the first hole auxiliary layer prime1-B′ and the second hole auxiliary layer prime2-B′ of the blue light emitting device 03 are 12 nm.

In some implementations, as shown in FIG. 3, the display panel includes a red light emitting device 01, a green light emitting device 02, and a blue light emitting device 03; where a hole mobility of the first hole auxiliary layer prime1-R′ of the red light emitting device 01 is greater than that of the first hole auxiliary layer prime1-G′ of the green light emitting device 02, and the hole mobility of the first hole auxiliary layer prime1-G′ of the green light emitting device 02 is greater than that of the first hole auxiliary layer prime1-B′ of the blue light emitting device 03; a hole mobility of the second hole auxiliary layer prime2-R′ of the red light emitting device 01 is greater than that of the second hole auxiliary layer prime2-G′ of the green light emitting device 02, and the hole mobility of the second hole auxiliary layer prime2-G′ of the green light emitting device 02 is greater than that of the second hole auxiliary layer prime2-B′ of the blue light emitting device 03.

For example, the hole mobilities of the first hole auxiliary layer prime1-R′ and the second hole auxiliary layer prime2-R′ of the red light emitting device 01 are the same, and the hole mobility of the first hole auxiliary layer prime1-R′ of the red light emitting device 01 is 4.5×10⁻⁴ cm²/(V·s).

For example, the hole mobilities of the first hole auxiliary layer prime1-G′ and the second hole auxiliary layer prime2-G′ of the green light emitting device 02 are the same, and the hole mobilities of the first hole auxiliary layer prime1-G′ and the second hole auxiliary layer prime2-G′ of the green light emitting device 02 are 5.6×10⁻⁵ cm²/(V·s).

For example, the hole mobilities of the first hole auxiliary layer prime1-B′ and the second hole auxiliary layer prime2-B′ of the blue light emitting device 03 are the same, and the hole mobilities of the first hole auxiliary layer prime1-B′ and the second hole auxiliary layer prime2-B′ of the blue light emitting device 03 are 9.3×10⁻⁶ cm²/(V. s).

In some implementations, the display panel includes a red light emitting device 01, a green light emitting device 02, and a blue light emitting device 03; where a material of the first hole auxiliary layer prime1-R′ and a material of the second hole auxiliary layer prime2-R′ in the red light emitting device 01 contain at least adamantane; a material of the first hole auxiliary layer prime1-G′ and a material of the second hole auxiliary layer prime2-G′ in the green light emitting device 02 contain at least fluorene-based material; a material of the first hole auxiliary layer prime1-B′ and a material of the second hole auxiliary layer prime2-B′ in the blue light emitting device 03 contain at least a dibenzo five-membered ring structure.

According to the display panel provided by the embodiment of the present disclosure, light emitting devices with different colors are formed by three different prime materials in combination with the material (i.e., the compound ET-1 to the compound ET-15) of the electron transport layer, the mobility of the hole auxiliary layer prime in the red light emitting device 01 is greater than that of the hole auxiliary layer prime in the green light emitting device 02, the mobility of the hole auxiliary layer prime in the green light emitting device 02 is greater than that of the hole auxiliary layer prime in the blue light emitting device 03, and the thickness of the red light emitting device 01 is the greatest and the thickness of the blue light emitting device 03 is the least, so that the efficiency and the service life of the display panel are improved.

Performance parameters of a full-color RGB display panel provided by the present disclosure and an existing RGB display panel are described below through comparison in an overall example.

In a third implementation, a full-color RGB display panel is prepared. Specifically, a first hole injection layer HIL1, a first hole transport layer HTL1, first hole auxiliary layers prime1-R′, prime 1-G′, prime1-B′, first light emitting layers EML1-R, EML1-G, and EML1-B, a first hole blocking layer HBL1, a first electron transport layer ETL1, an N-type doped charge generation layer N-CGL, a P-type doped charge generation layer P-CGL, a second hole transport layer HTL2, second hole auxiliary layers prime2-R′, prime2-G′, and prime2-B′, second light emitting layers EML2-R, EML2-G, and EML2-B, a second hole blocking layer HBL2, a second electron transport layer ETL2, a second electron injection layer EIL2, and a cathode 2 may be sequentially evaporated on an ITO base substrate.

FIG. 4 is a schematic diagram of some layers in a display panel according to an embodiment of the present disclosure. As shown in FIG. 4, it should be noted that the first hole auxiliary layers prime1-R′, prime1-G′, and prime1-B′ are independent structures, and are all disposed on a side of the first hole transport layer HTL1 away from an anode 1, the thickness of the first hole auxiliary layer prime1-R′ is 80 nm, the thickness of the first hole auxiliary layer prime1-G′ is 30 nm, and the thickness of the first hole auxiliary layer prime1-B′ is 10 nm. The first hole auxiliary layer prime1-R′ is made of the compound J-1, the first hole auxiliary layer prime1-G′ is made of the compound W-1, and the first hole auxiliary layer prime1-B′ is made of the compound X-1. The material of the red light emitting layer is RH: RD (2%), the material of the green light emitting layer is GH: GD (8%), and the material of the blue light emitting layer is BH: BD (2%). The thickness of the red light emitting layer is 55 nm, the thickness of the green light emitting layer is 35 nm, and the thickness of the blue light emitting layer is 20 nm.

It should be noted that here, in each light emitting device, the material, thickness, and hole mobility of the first hole auxiliary layer prime1 are the same as those of the second hole auxiliary layer prime2.

In addition, other functional layers of the light emitting devices with different colors in the full-color RGB display panel have a one-piece structure. The thickness of the first hole injection layer HIL1 is 10 nm, the thickness of the first hole transport layer HTL1 is 20 nm, the thickness of the first hole blocking layer HBL1 is 5 nm, the thickness of the first electron transport layer ETL1 is 5 nm, the thickness of the N-type doped charge generation layer N-CGL is 18 nm, the thickness of the P-type doped charge generation layer P-CGL is 90 nm, the thickness of the second hole transport layer HTL2 is 40 nm, the thickness of the second hole blocking layer HBL2 is 5 nm, the thickness of the second electron transport layer ETL2 is 30 nm, the thickness of the second electron injection layer EIL2 is 1 nm, and the thickness of the cathode 2 is 13 nm.

For the preparation of the display panel in the comparative example, the material of the hole auxiliary layer in the display panel is replaced by prime-R′-T, prime-G′-T and prime-B′-T, and other structures are unchanged.

The display panel is tested for voltage, efficiency and service life according to the above structures, and the specific data results are shown in the table 4.

TABLE 4

| | | | | Voltage | Efficiency | Service |
|---|---|---|---|---|---|---|
| | R′ | G′ | B′ | (V) | (cd/cm²) | life (h) |
| Full-color RGB | J-I | W-1 | X-1 | 98% | 113% | 154% |
| display panel | | | | | | |
| Electron mobility | 4.5 × 10⁻⁴ | 5.6 × 10⁻⁵ | 9.3 × 10⁻⁶ | | | |
| (cm²/(V · s)) | | | | | | |
| Thickness (nm) | 80 | 30 | 10 | | | |
| Display panel in the | R′-T | G′-T | B′-T | 100% | 100% | 100% |
| comparative example | | | | | | |
| Electron mobility | 5.1 × 10⁻⁵ | 4.1 × 10⁻⁵ | 7.3 × 10⁻⁶ | | | |
| (cm²/(V · s)) | | | | | | |

It can be seen from above that, the display panel is prepared by using the materials of the three hole auxiliary layers prime provided by the embodiment of the present disclosure in combination with the material of the electron transport layer ETL, which can finally realize the improvement of the efficiency and the service life of the display panel.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the protective scope of the present disclosure.

1. A light emitting device, comprising an anode, a cathode, a plurality of light emitting units between the anode and the cathode, and a charge separation generation unit between every two adjacent light emitting units;
the plurality of light emitting units comprise a first light emitting unit and a second light emitting unit, and the first light emitting unit is closer to the anode than the second light emitting unit; and
the first light emitting unit at least comprises a first electron transport sub-unit, the second light emitting unit at least comprises a second electron transport sub-unit, and a thickness of the first electron transport sub-unit is less than that of the second electron transport sub-unit.

2. The light emitting device according to claim 1, wherein the first electron transport sub-unit comprises a first hole blocking layer and a first electron transport layer, which are sequentially provided in a direction from the anode to the cathode; the second electron transport sub-unit comprises a second hole blocking layer and a second electron transport layer, which are sequentially provided in the direction from the anode to the cathode; the charge separation generation unit comprises an N-type doped charge generation layer and a P-type doped charge generation layer, which are sequentially provided in the direction from the anode to the cathode.

3. The light emitting device according to claim 2, wherein a sum of thicknesses of the first electron transport layer and the first hole blocking layer is a first thickness; a sum of thicknesses of the second electron transport layer and the second hole blocking layer is a second thickness; a difference between the second thickness and the first thickness is between 50 Å and 350 Å;
the difference between the thicknesses of the second electron transport layer and the first electron transport layer is between 50 Å and 300 Å; and
the thickness of the first electron transport layer is less than that of the second electron transport layer.

4-5. (canceled)

6. The light emitting device according to claim 1, wherein the first electron transport sub-unit comprises a first electron transport layer; the second electron transport sub-unit comprises a second electron transport layer; and
a difference between thicknesses of the second electron transport layer and the first electron transport layer is between 50 Å and 300 Å.

7. The light emitting device according to claim 2, wherein an absolute value of a difference between a LUMO level of a lowest unoccupied molecular orbital of the N-type doped charge generation layer and a LUMO level of a lowest unoccupied molecular orbital of the first electron transport layer is between 0.1 eV and 0.6 eV;
a material of the N-type doped charge generation layer is doped with ytterbium Yb or lithium Li, a doping concentration of the ytterbium Yb or lithium Li is greater than or equal to 1%; and
the N-type doped charge generation layer has a thickness between 100 Å and 250 Å.

8-9. (canceled)

10. The light emitting device according to claim 2, wherein an absolute value of a difference between a LUMO level of the first electron transport layer and a LUMO level of the first hole blocking layer is between 0.1 eV and 0.8 eV;
an electron mobility of the first electron transport layer is greater than that of the first hole blocking layer;
a material of the first electron transport layer and a material of the second electron transport layer are the same;
a material layer of the first electron transport layer and a material of the second electron transport layer are different from each other; and an absolute value of a difference between a LUMO level of the first electron transport layer and a LUMO level of the second electron transport layer is between 0 eV and 0.4 eV.

11-13. (canceled)

14. The light emitting device according to claim 2, wherein a material of the first electron transport layer and a material of the second electron transport layer have the following general structural formula: 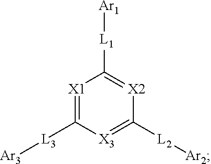
Where, X₁, X₂ and X₃ each independently represent carbon C or nitrogen N, and at least one of X₁, X₂ and X₃ is N; L₁, L₂ and L₃ each independently represent a connecting group and any one selected from a single bond, a substituted or unsubstituted C6 to C20 aryl group and a substituted or unsubstituted C5 to C20 heteroaryl group; Ar₁, Ar₂ and Ar₃ each independently represent any one selected from a substituted or unsubstituted C6 to C20 aryl group and a substituted or unsubstituted C5 to C20 heteroaryl group.

15. The light emitting device according to claim 10, wherein the structure of each of the material of the first electron transport layer and the material of the second electron transport layer comprises any one of:

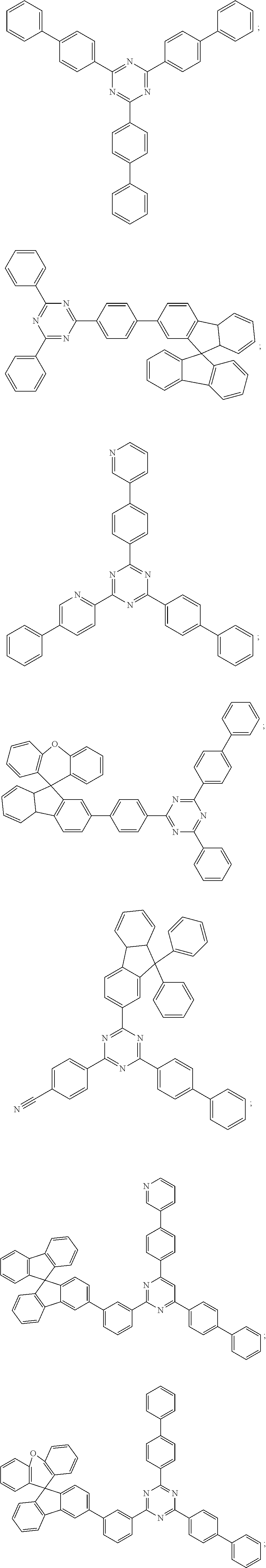

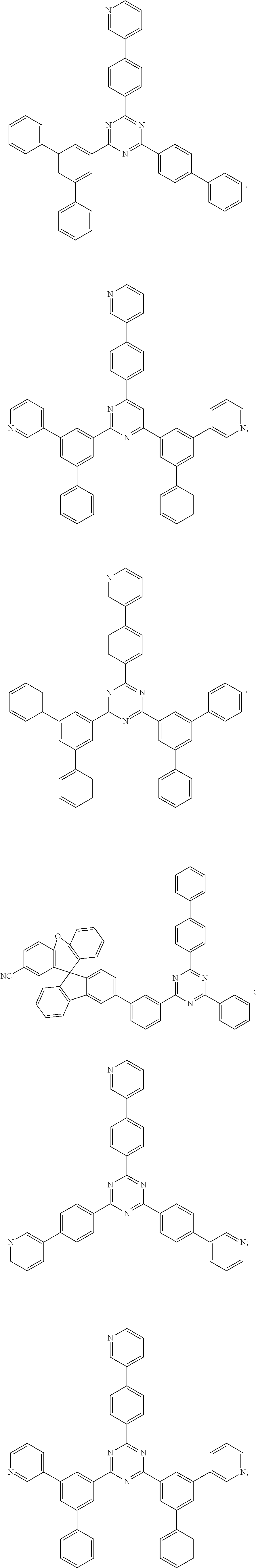

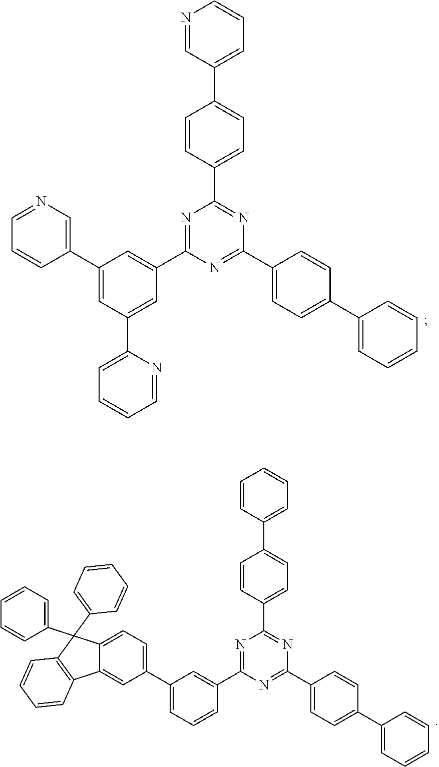 [SMILES: c1ccc(-c2ccc(-c3nc(-c4ccc(-c5cccnc5)cc4)nc(-c4cc(-c5cccnc5)cc(-c5ccccn5)c4)n3)cc2)cc1 ; c1ccc(-c2ccc(-c3nc(-c4ccc(-c5ccccc5)cc4)nc(-c4cccc(-c5ccc6c(c5)-c5ccccc5C6(c5ccccc5)c5ccccc5)c4)n3)cc2)cc1]

16. The light emitting device according to claim 1, wherein the first light emitting unit further comprises a first hole transport sub-unit comprising a first hole transport layer and a first hole auxiliary layer, which are sequentially provided in a direction from the anode to the cathode; and
the second light emitting unit further comprises a second hole transport sub-unit comprising a second hole transport layer and a second hole auxiliary layer, which are sequentially provided in the direction from the anode to the cathode.

17. The light emitting device according to claim 16, wherein materials of the first hole auxiliary layer and the second hole auxiliary layer have the following general structural formula: 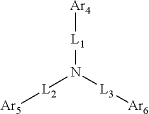
where, L₁, L₂ and L₃ each independently represent a connecting group and any one selected from a single bond, a substituted or unsubstituted C6 to C20 aryl group and a substituted or unsubstituted C5 to C20 heteroaryl group; Ar₄, Ar₅ and Ar₆ all independently represent any one selected from a C6 to C50 aryl group and a substituted or unsubstituted C5 to C50 heteroaryl group, a fluorene-based material, a dibenzo five-membered ring structure and adamantane.

18. The light emitting device according to claim 17, wherein a structure of the fluorene-based material comprises at least one of.

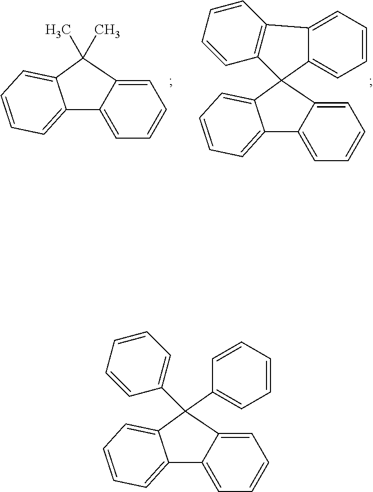

19. The light emitting device according to claim 18, wherein a structure of each of the material of the first hole auxiliary layer comprising the fluorene-based material and the material of the second hole auxiliary layer comprising the fluorene-based material comprises any one of

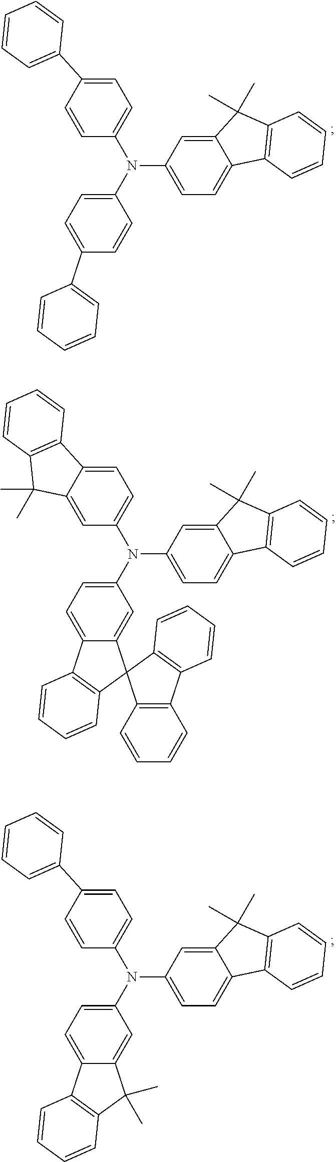 [SMILES: CC1(C)c2ccccc2-c2ccc(N(c3ccc(-c4ccccc4)cc3)c3ccc(-c4ccccc4)cc3)cc21 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C(C)(C)c3ccccc3-4)cc21]

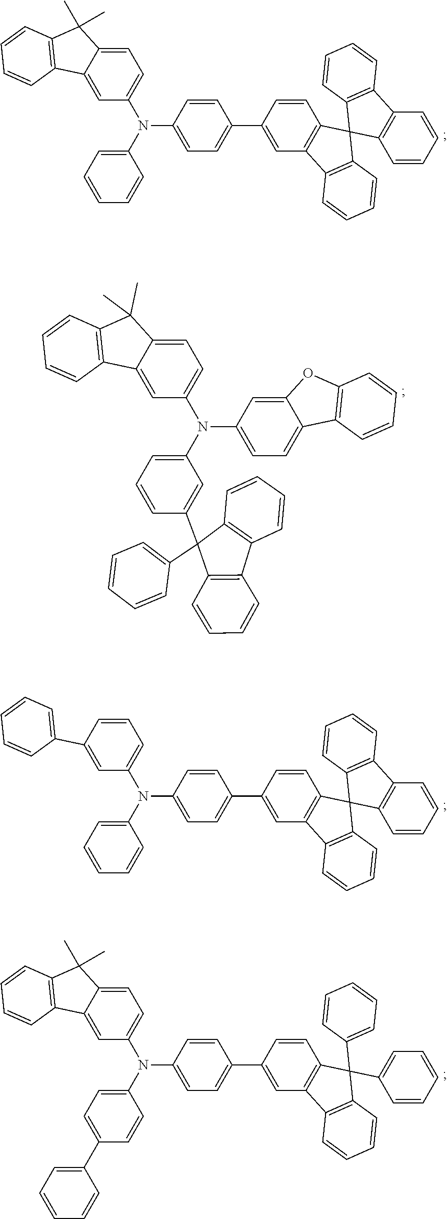 [SMILES: CC1(C)c2ccccc2-c2cc(N(c3ccccc3)c3ccc(-c4ccc5c(c4)-c4ccccc4C54c5ccccc5-c5ccccc54)cc3)ccc21 ; CC1(C)c2ccccc2-c2cc(N(c3cccc(C4(c5ccccc5)c5ccccc5-c5ccccc54)c3)c3ccc4c(c3)oc3ccccc34)ccc21 ; c1ccc(-c2cccc(N(c3ccccc3)c3ccc(-c4ccc5c(c4)-c4ccccc4C54c5ccccc5-c5ccccc54)cc3)c2)cc1 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21]

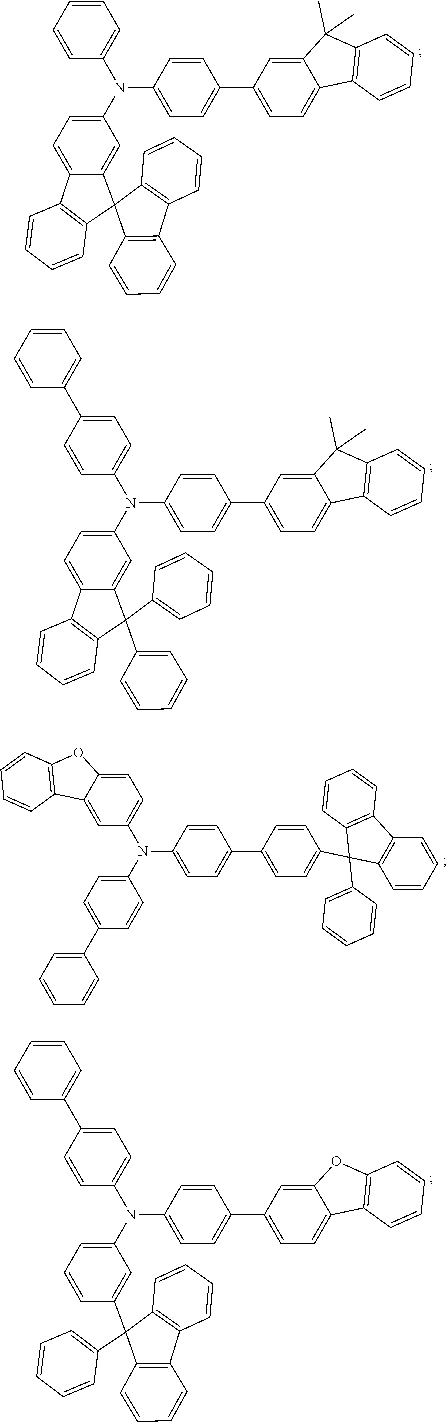

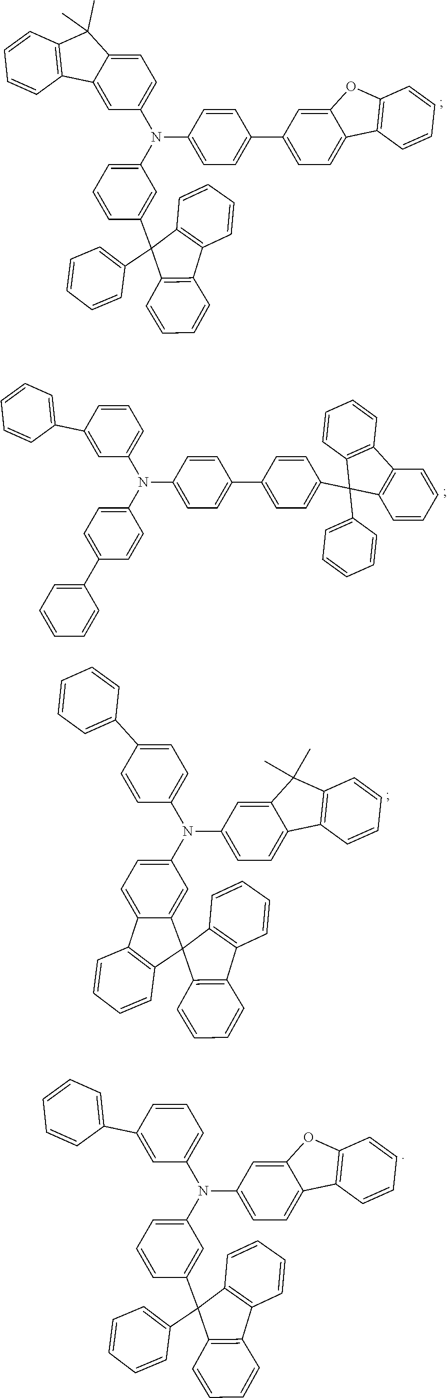

20. The light emitting device according to claim 17, wherein the dibenzo five-membered ring structure comprises a structure of: 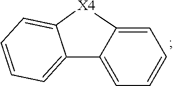
wherein, X4 is nitrogen N, oxygen O or sulfur S.

21. The light emitting device according to claim 20, wherein a structure of each of a material of the first hole auxiliary layer containing the dibenzo five-membered ring structure and a material of the second hole auxiliary layer containing the dibenzo five-membered ring structure comprises any one of:

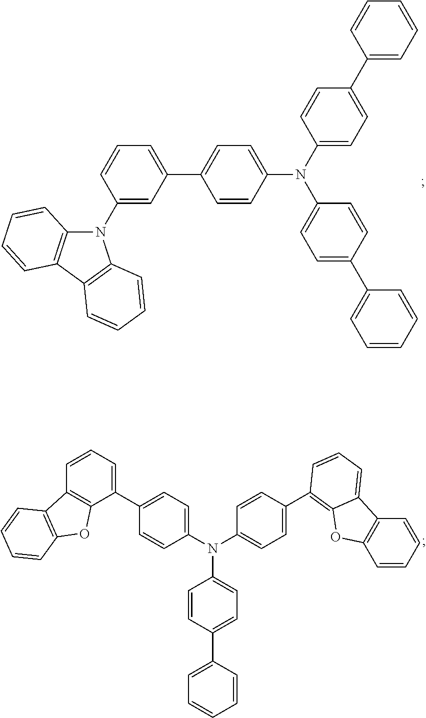 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1]

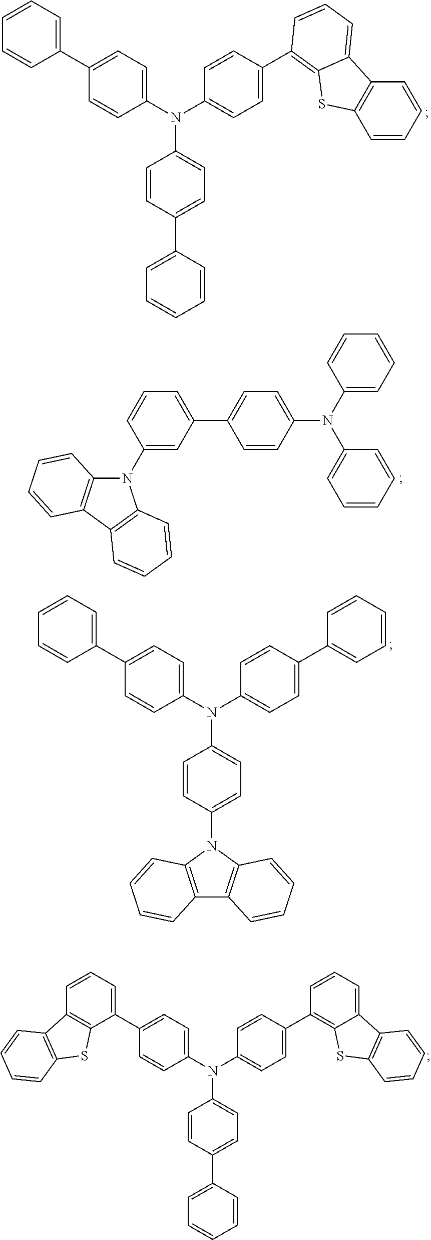 [SMILES: c1ccc(-c2ccc(N(c3ccc(-c4ccccc4)cc3)c3ccc(-c4cccc5c4sc4ccccc45)cc3)cc2)cc1 ; c1ccc(N(c2ccccc2)c2ccc(-c3cccc(-n4c5ccccc5c5ccccc54)c3)cc2)cc1 ; c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4cccc5c4sc4ccccc45)cc3)c3ccc(-c4cccc5c4sc4ccccc45)cc3)cc2)cc1]

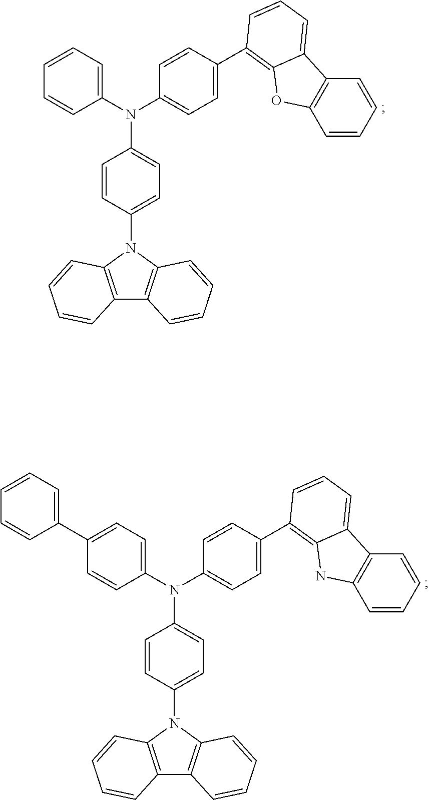 [SMILES: c1ccc(N(c2ccc(-c3cccc4c3oc3ccccc34)cc2)c2ccc(-n3c4ccccc4c4ccccc43)cc2)cc1 ; c1ccc(-c2ccc(N(c3ccc(-c4cccc5c4[nH]c4ccccc45)cc3)c3ccc(-n4c5ccccc5c5ccccc54)cc3)cc2)cc1]

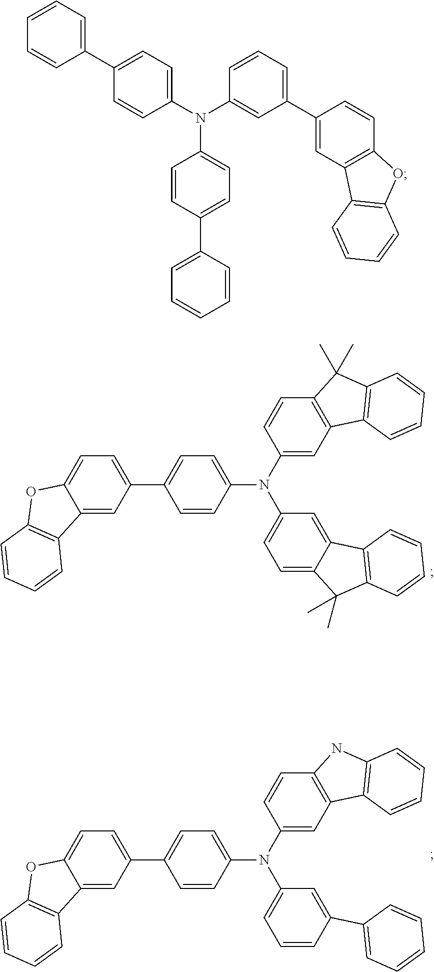 [SMILES: c1ccc(-c2ccc(N(c3ccc(-c4ccccc4)cc3)c3cccc(-c4ccc5oc6ccccc6c5c4)c3)cc2)cc1 ; CC1(C)c2ccccc2-c2cc(N(c3ccc(-c4ccc5oc6ccccc6c5c4)cc3)c3ccc4c(c3)-c3ccccc3C4(C)C)ccc21 ; c1ccc(-c2cccc(N(c3ccc(-c4ccc5oc6ccccc6c5c4)cc3)c3ccc4[nH]c5ccccc5c4c3)c2)cc1]

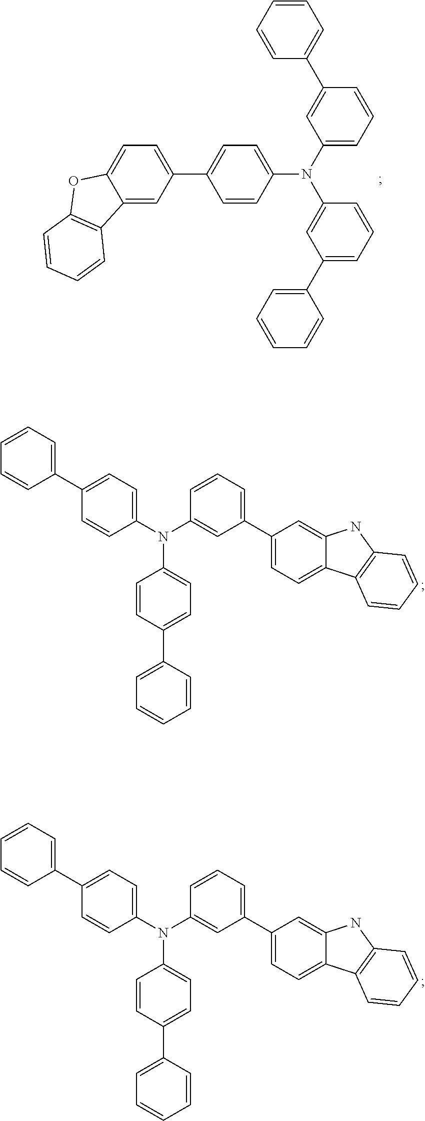 [SMILES: c1ccc(-c2cccc(N(c3ccc(-c4ccc5oc6ccccc6c5c4)cc3)c3cccc(-c4ccccc4)c3)c2)cc1 ; c1ccc(-c2ccc(N(c3ccc(-c4ccccc4)cc3)c3cccc(-c4ccc5c(c4)[nH]c4ccccc45)c3)cc2)cc1 ; c1ccc(-c2ccc(N(c3ccc(-c4ccccc4)cc3)c3cccc(-c4ccc5c(c4)[nH]c4ccccc45)c3)cc2)cc1]

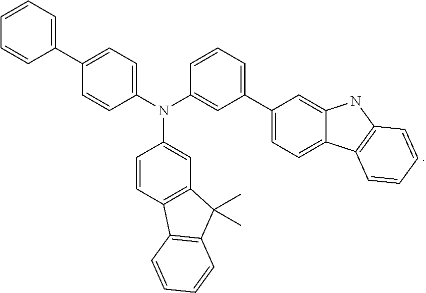 [SMILES: CC1(C)c2ccccc2-c2ccc(N(c3ccc(-c4ccccc4)cc3)c3cccc(-c4ccc5c(c4)[nH]c4ccccc45)c3)cc21]

22. The light emitting device according to claim 17, wherein a structure of the material of adamantane comprises:

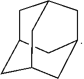

23. The light emitting device according to claim 22, wherein a structure of each of the material of the first hole auxiliary layer containing the adamantane and the material of the second hole auxiliary layer containing the adamantane comprises any one of:

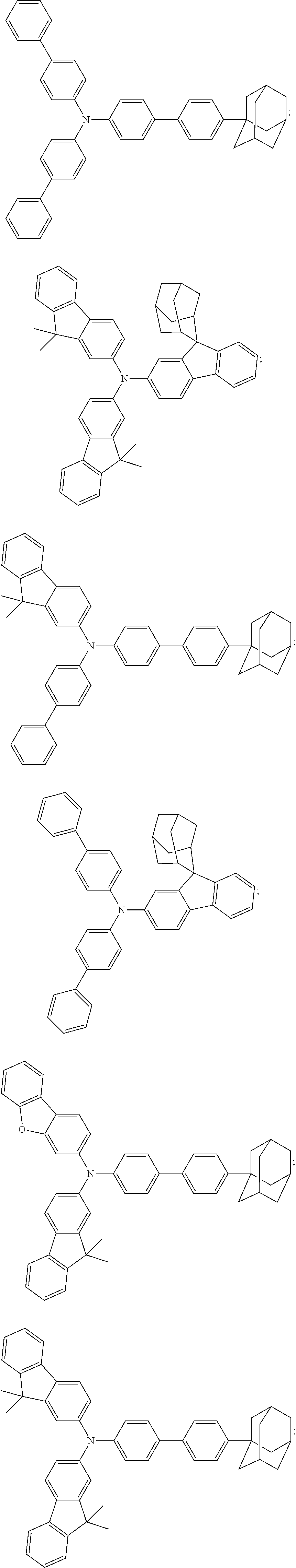

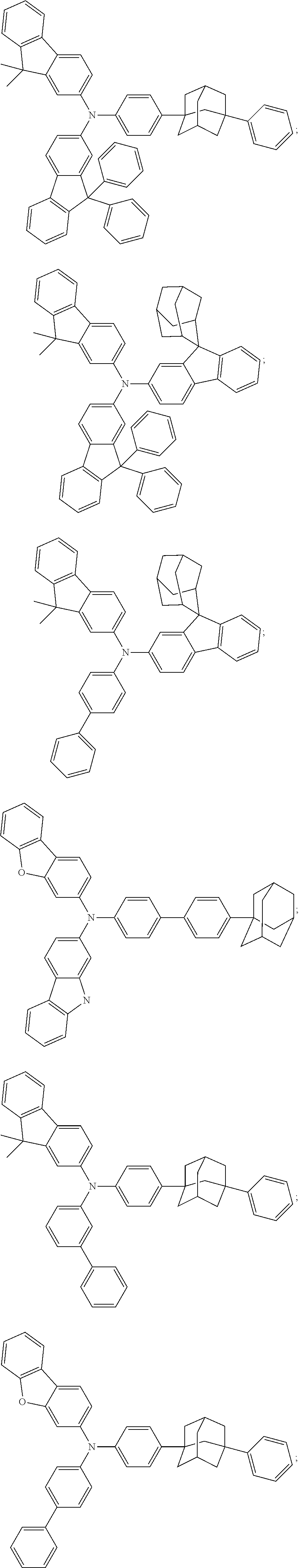

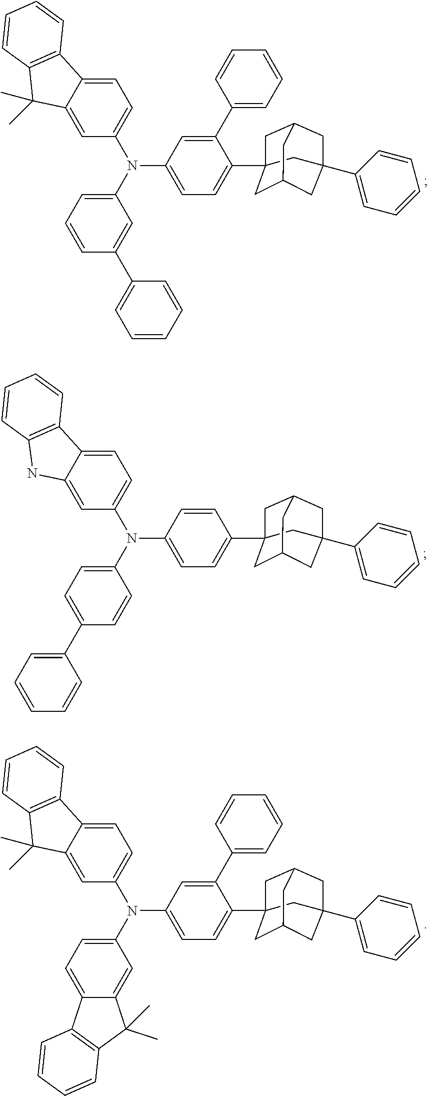

24. A display panel, comprising the light emitting device according to claim 1.

25. The display panel according to claim 24, wherein the first light emitting unit comprises a first hole transport sub-unit at least comprising a first hole auxiliary layer; and the second light emitting unit comprises a second hole transport sub-unit at least comprising a second hole auxiliary layer;
the display panel comprises a red light emitting device, a green light emitting device, and a blue light emitting device; wherein a thickness of the first hole auxiliary layer of the red light emitting device is greater than that of the first hole auxiliary layer of the green light emitting device, and the thickness of the first hole auxiliary layer of the green light emitting device is greater than that of the first hole auxiliary layer of the blue light emitting device; and
a thickness of the second hole auxiliary layer of the red light emitting device is greater than that of the second hole auxiliary layer of the green light emitting device, and the thickness of the second hole auxiliary layer of the green light emitting device is greater than that of the second hole auxiliary layer of the blue light emitting device.

26. The display panel according to claim 24, wherein the first light emitting unit comprises a first hole transport sub-unit at least comprising a first hole auxiliary layer; and the second light emitting unit comprises a second hole transport sub-unit at least comprising a second hole auxiliary layer;
the display panel comprises a red light emitting device, a green light emitting device, and a blue light emitting device; wherein a hole mobility of the first hole auxiliary layer of the red light emitting device is greater than that of the first hole auxiliary layer of the green light emitting device, and the hole mobility of the first hole auxiliary layer of the green light emitting device is greater than that of the first hole auxiliary layer of the blue light emitting device; and
a hole mobility of the second hole auxiliary layer of the red light emitting device is greater than that of the second hole auxiliary layer of the green light emitting device, and the hole mobility of the second hole auxiliary layer of the green light emitting device is greater than that of the second hole auxiliary layer of the blue light emitting device.

27. The display panel according to claim 24, wherein the first light emitting unit comprises a first hole transport sub-unit at least comprising a first hole auxiliary layer; and the second light emitting unit comprises a second hole transport sub-unit at least comprising a second hole auxiliary layer; and
the display panel comprises a red light emitting device, a green light emitting device, and a blue light emitting device; wherein a material of the first hole auxiliary layer and a material of the second hole auxiliary layer in the red light emitting device at least comprise adamantane; a material of the first hole auxiliary layer and a material of the second hole auxiliary layer in the green light emitting device at least comprise fluorene-based material; and a material of the first hole auxiliary layer and a material of the second hole auxiliary layer in the blue light emitting device at least comprise a dibenzo five-membered ring structure.
